(19) United States
(12) Patent Application Publication
(10) Pub. No.: US 2023/0313037 A1
(43) Pub. Date: Oct. 5, 2023

(54) METHOD OF PREPARING QUANTUM DOT, QUANTOM DOT PREPARED THEREBY, OPTICAL MEMBER INCLUDING THE QUANTUM DOT, AND ELECTRONIC APPARATUS INCLUDING THE QUANTUM DOT

(71) Applicants: Samsung Display Co., Ltd., Yongin-si (KR); Korea Advanced Institute of Science and Technology, Daejeon (KR)

(72) Inventors: Sooho Lee, Yongin-si (KR); Dohchang Lee, Daejeon (KR); Sangmin Yeo, Daejeon (KR)

(21) Appl. No.: 18/118,631

(22) Filed: Mar. 7, 2023

(30) Foreign Application Priority Data
Mar. 29, 2022 (KR) 10-2022-0039171

(51) Int. Cl. C09K 11/70; C09K 11/56; F21V 9/30

(52) U.S. Cl. CPC C09K 11/70; C09K 11/565; F21V 9/30; H10K 50/115

(57) ABSTRACT

A method of preparing a quantum dot, a quantum dot prepared by the method, and an optical member and an electronic apparatus that include the quantum dot are provided. The method includes injecting a first solvent into a first reaction vessel, preparing a first composition by injecting a first semiconductor compound into the first reaction vessel, and forming a first shell by injecting a second composition including the second precursor into the first reaction vessel.

### CROSS-REFERENCE TO RELATED APPLICATION

This application claims priority to and the benefit of Korean Patent Application No. 10-2022-0039171, filed on Mar. 29, 2022, in the Korean Intellectual Property Office, the entire content of which is hereby incorporated by reference.

### BACKGROUND

### 1. Field

Aspects of one or more embodiments of the present disclosure relate to a method of preparing a quantum dot, a quantum dot prepared by the method, an optical member including the quantum dot, and an electronic device including the quantum dot.

### 2. Description of the Related Art

Quantum dots may be utilized as materials that perform one or more suitable optical functions (for example, a light conversion function, a light emission function, and/or the like) in optical members and/or in one or more suitable electronic apparatuses. Quantum dots, which are semiconductor nanocrystals with a quantum confinement effect, may have different energy bandgaps by control of (selection of) the size and composition of the nanocrystals, and accordingly may emit light of suitable (various) emission wavelength(s).

An optical member including such quantum dots may have the form of a thin film, for example, a thin film patterned for each subpixel. Such an optical member may be utilized as a color conversion member of a device including one or more suitable light sources.

The quantum dots may be utilized for a variety of purposes in one or more suitable electronic apparatuses. For example, the quantum dots may be utilized as emitters. For example, the quantum dots may be included in an emission layer of a light-emitting device, including a pair of electrodes and the emission layer (e.g., therebetween), and may serve as an emitter.

Currently, to realize a high-quality optical member and electronic device, there is a need for the development of quantum dots that emit blue light, have excellent or suitable luminescence quantum efficiency (PLQY), and do not contain cadmium (e.g., not contain any cadmium), which is a toxic element.

### SUMMARY

Aspects of one or more embodiments of the present disclosure are directed toward a method of preparing a quantum dot, a quantum dot prepared by the method, an optical member including the quantum dot, and an electronic device including the quantum dot.

Additional aspects will be set forth in part in the description which follows and, in part, will be apparent from the description, or may be learned by practice of the presented embodiments of the disclosure.

According to one or more embodiments of the present disclosure, a method of preparing a quantum dot includes
injecting a first solvent into a first reaction vessel,
preparing a first composition by injecting a first semiconductor compound into the first reaction vessel, and
forming a first shell by injecting a second composition including a second precursor into the first reaction vessel,
wherein the first semiconductor compound includes A¹ and B¹,
the second precursor includes A² and B²,
A¹ and A² may each independently be a metal element and are different from each other, and
B¹ and B² may each independently be a non-metal element.

According to one or more embodiments,
a quantum dot prepared by the method includes
a core including the first semiconductor compound, and
a first shell covering the core,
wherein the first shell includes A² and B².

According to one or more embodiments, an optical member includes the quantum dot.

According to one or more embodiments, an electronic apparatus includes the quantum dot.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a schematic cross-sectional view of a quantum dot according to an embodiment;

FIG. 2 is a schematic cross-sectional view of a quantum dot according to an embodiment;

FIG. 3 is a schematic view showing a structure of an electronic apparatus according to an embodiment;

FIG. 4 is a schematic view showing an electronic apparatus according to another embodiment;

FIG. 5 is a graph showing absorbance spectra of quantum dots of Examples 1-1 to 1-3 and a control group;

FIGS. 6A-6E are each a transmission electron microscope (TEM) image of quantum dots of Examples 1-1, 1-2, and 1-3 and of a control group; and

FIG. 7 is a graph showing photoluminescence spectra of quantum dots of Examples 2-1, 2-2, and 2-3 and of a control group.

### DETAILED DESCRIPTION

Reference will now be made in more detail to embodiments, examples of which are illustrated in the accompanying drawings, wherein like reference numerals refer to like elements throughout, and duplicative descriptions thereof may not be provided. In this regard, the present embodiments may have different forms and should not be construed as being limited to the descriptions set forth herein. Accordingly, the embodiments are merely described below, by referring to the drawings, to explain aspects of the present disclosure. As utilized herein, the term “and/or” includes any and all combinations of one or more of the associated listed items. Throughout the disclosure, the expression “at least one of a, b or c”, “at least one selected from among a, b, and c,” etc., indicates only a, only b, only c, both (e.g., simultaneously) a and b, both (e.g., simultaneously) a and c, both (e.g., simultaneously) b and c, all of a, b, and c, or variations thereof.

Because the disclosure may have diverse modified embodiments, embodiments are illustrated in the drawings and are described in the detailed description. An effect and a characteristic of the disclosure, and a method of accomplishing these will be apparent when referring to embodiments described with reference to the drawings. The disclosure may, however, be embodied in many different forms and should not be construed as limited to the embodiments set forth herein.

It will be understood that although the terms “first,” “second,” etc. utilized herein may be utilized herein to describe one or more suitable components, these components should not be limited by these terms. These components are only utilized to distinguish one component from another.

An expression utilized in the singular encompasses the expression of the plural, unless it has a clearly different meaning in the context.

In the present disclosure, it is to be understood that the terms such as “including,” “having,” and “including” are intended to indicate the existence of the features or components disclosed in the disclosure, and are not intended to preclude the possibility that one or more other features or components may exist or may be added. For example, unless otherwise limited, terms such as “including” or “having” may refer to either consisting of features or components described in the disclosure only or further including other components.

The term “Group II” as utilized herein may include a Group IIA element and/or a Group IIB element on the IUPAC periodic table, and the Group II element may include, for example, magnesium (Mg), calcium (Ca), zinc (Zn), cadmium (Cd), mercury (Hg), and/or the like.

The term “Group III” as utilized herein may include a Group IIIA element and/or a Group IIIB element on the IUPAC periodic table, and the Group III element may include, for example, aluminum (Al), gallium (Ga), indium (In), thallium (Tl), and/or the like.

The term “Group V” as utilized herein may include a Group VA element and/or a Group VB element on the IUPAC periodic table, and the Group V element may include, for example, nitrogen (N), phosphorus (P), arsenic (As), antimony (Sb), and/or the like.

The term “Group VI” as utilized herein may include a Group VIA element and/or a Group VIB element on the IUPAC periodic table, and the Group VI element may include, for example, sulfur (S), selenium (Se), tellurium (Te), and/or the like.

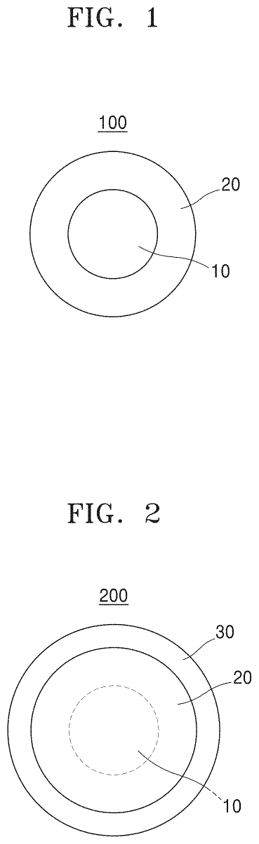

Hereinafter, a quantum dot 100 or 200 and a method of preparing the same according to embodiments of the present disclosure will be described in more detail with reference to FIGS. 1 and 2.

### Description of FIG. 1

FIG. 1 is a schematic cross-sectional view of a quantum dot 100 according to an embodiment. The quantum dot 100 may include a core 10 and a first shell 20.

### Quantum Dot 100

The quantum dot 100 of FIG. 1 may include: a core 10 including a first semiconductor compound; and a first shell 20 around (e.g., covering) the core, wherein
the first shell may include a second semiconductor compound,
the first semiconductor compound may include A¹ and B¹,
the second semiconductor compound may include A² and B²,
A¹ and A² may each independently be a metal element and may be different from each other, and
B¹ and B² may each independently be a non-metal element.

In an embodiment, A¹ and A² may each independently include a Group II element, a Group III element, or a combination thereof.
For example, A¹ and A² may each independently include beryllium (Be), magnesium (Mg), calcium (Ca), strontium (Sr), barium (Ba), zinc (Zn), cadmium (Cd), mercury (Hg), scandium (Sc), aluminum (Al), gallium (Ga), indium (In), thallium (Tl), or one or more combinations thereof.

In an embodiment, B¹ and B² may each independently include a Group V element, a Group VI element, or a combination thereof.

For example, B¹ and B² may each independently include vanadium (V), niobium (Nb), nitrogen (N), phosphorus (P), arsenic (As), antimony (Sb), oxygen (O), sulfur (S), selenium (Se), tellurium (Te), or one or more combinations thereof.

In an embodiment, B¹ and B² may be identical to or different from each other.

In an embodiment, the first semiconductor compound may include a binary compound, a ternary compound, a quaternary compound, or one or more combinations thereof.

In an embodiment, the first semiconductor compound may include a Group II-VI semiconductor compound, a Group III-V semiconductor compound, a Group V semiconductor compound, a Group III-VI semiconductor compound, or one or more combinations thereof.

In an embodiment, the first semiconductor compound may be represented by Formula 1:

A¹¹₁₋ₓ₁A¹²ₓ₁B¹³_{y1} Formula 1

wherein, in Formula 1,
A¹¹ may be a Group III element,
A¹² may be a Group II element,
B¹¹ may be a Group V element or a Group VI element,
x1 may be an integer greater than or equal to 0 and less than 1, and
y1 may be an integer greater than 0 and less than or equal to 1.

In one or more embodiments, the first semiconductor compound may be represented by Formula 1-1:

In₁₋ₓ₁Znₓ₁P_{y1} Formula 1-1

wherein, in Formula 1-1,
x1 may be an integer greater than or equal to 0 and less than 1, and
y1 may be an integer greater than 0 and less than or equal to 1.

In an embodiment, the second semiconductor compound may be represented by Formula 2:

A²¹₁₋ₓ₂A²²ₓ₂B²¹_{y2} Formula 2

wherein, in Formula 2,
A²¹ may be a Group III element,
A²² may be a Group II element,
B²² may be a Group V element or a Group VI element,
x2 may be an integer greater than or equal to 0 and less than or equal to 1, and
y2 may be an integer greater than 0 and less than or equal to 1.

In an embodiment, the second semiconductor compound may include a binary compound, a ternary compound, a quaternary compound, or one or more combinations thereof.

In an embodiment, the second semiconductor compound may include a Group II-VI semiconductor compound, a Group III-V semiconductor compound, a Group II-III-V semiconductor compound, a Group III-VI semiconductor compound, or one or more combinations thereof.

For example, the first semiconductor compound and the second semiconductor compound may each independently be: CdS, CdSe, CdTe, ZnS, ZnSe, ZnTe, ZnO, HgS, HgSe, HgTe, MgSe, MgS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, CdZnSeS, CdZnSeTe, CdZnSTe, CdHgSeS, CdHgSeTe, CdHgSTe, HgZnSeS, HgZnSeTe, or HgZnSTe;
GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, or InAlPSb;
InZnP, InGaZnP, or InAlZnP;
GaS, GaSe, Ga₂Se₃, GaTe, InS, InSe, In₂S₃, In₂Se₃, InTe, InGaS₃, or InGaSe₃; or one or more combinations thereof.

In an embodiment, an average particle diameter D50 of the core 10 may be greater than or equal to about 1.0 nm and less than or equal to about 4.0 nm.

In an embodiment, the first semiconductor compound may have a substantially spherical shape.

In an embodiment, an average particle diameter D50 of the first semiconductor compound may be greater than or equal to about 1.0 nm and less than or equal to about 4.0 nm.

In an embodiment, the core 10 may include (e.g., consist of) the first semiconductor compound.

In an embodiment, an average particle diameter D50 of the quantum dot 100 may be greater than or equal to about 1 nm and less than or equal to 10 nm, for example, greater than or equal to about 1 nm and less than or equal to 8 nm, or greater than or equal to about 2 nm and less than or equal to 5 nm.

In an embodiment, an average particle diameter D50 of the first shell 20 may be greater than or equal to about 1 nm and less than or equal to about 8 nm, or greater than or equal to about 2 nm and less than or equal to 5 nm.

In an embodiment, the quantum dot 100 may have a substantially spherical shape.

In an embodiment, a concentration of A² in the first shell 20 may be substantially uniform.

In an embodiment, a concentration of B² in the first shell 20 may be substantially uniform.

In an embodiment, a concentration of the second semiconductor compound in the first shell 20 may be substantially uniform.

In an embodiment, a maximum emission wavelength in a PL spectrum of the quantum dot 100 may be in a range of about 450 nm to about 580 nm, about 450 nm to about 550 nm, or about 450 nm to about 530 nm.

In an embodiment, the quantum dot 100 may be prepared by a method of preparing a quantum dot to be described in more detail.

### Description of FIG. 2

FIG. 2 is a schematic cross-sectional view of a quantum dot 200 according to another embodiment. The quantum dot 200 may include the core 10, the first shell 20, and a second shell 30.

### Quantum Dot 200

The quantum dot 200 of FIG. 2 may include: the core 10 including the first semiconductor compound;
the first shell 20 around (e.g., covering) the core 10; and
a second shell 30 around (e.g., covering) at least a portion of the first shell 20, wherein
the second shell 30 may include A³ and B³, and
A³ may be a metal element, and B³ may be a non-metal element.

The first semiconductor compound, the core 10, and the first shell 20 may respectively be the same as defined herein.

In an embodiment, the second shell 30 may include a third semiconductor compound, and the third semiconductor compound may include A³ and B³.

In an embodiment, the third semiconductor compound may include: a Group II-VI semiconductor compound; a Group III-V semiconductor compound; a Group III-VI semiconductor compound; a Group I-III-VI semiconductor compound; a Group IV-VI semiconductor compound; a Group IV element or compound; or one or more combinations thereof.

Examples of the Group II-VI semiconductor compound may include: a binary compound, such as CdS, CdSe, CdTe, ZnS, ZnSe, ZnTe, ZnO, HgS, HgSe, HgTe, MgSe, MgS, and/or the like; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and/or the like; a quaternary compound, such as CdZnSeS, CdZnSeTe, CdZnSTe, CdHgSeS, CdHgSeTe, CdHgSTe, HgZnSeS, HgZnSeTe, HgZnSTe, and/or the like; or one or more combinations thereof.

Examples of the Group III-V semiconductor compound may include: a binary compound, such as GaN, GaP, GaAs, GaSb, AlN, AlP, AlAs, AlSb, InN, InP, InAs, InSb, and/or the like; a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, and/or the like; a quaternary compound, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and/or the like; or one or more combinations thereof. In an embodiment, the Group III-V semiconductor compound may further include a Group II element. Examples of the Group III-V semiconductor compound further including the Group II element may be InZnP, InGaZnP, InAlZnP, and/or the like.

Examples of the Group III-VI semiconductor compound may include: a binary compound, such as GaS, GaSe, Ga₂Se₃, GaTe, InS, InSe, In₂S₃, In₂Se₃, InTe, and/or the like; a ternary compound, such as InGaS₃, InGaSe₃, and/or the like; or one or more combinations thereof.

Examples of the Group I-III-VI semiconductor compound may include: a ternary compound, such as AgInS, AgInS₂, CuInS, CuInS₂, CuGaO₂, AgGaO₂, AgAlO₂, and/or the like; or one or more combinations thereof.

Examples of the Group IV-VI semiconductor compound may include: a binary compound, such as SnS, SnSe, SnTe, PbS, PbSe, PbTe, and/or the like; a ternary compound, such as SnSeS, SnSeTe, SnSTe, PbSeS, PbSeTe, PbSTe, SnPbS, SnPbSe, SnPbTe, and/or the like; a quaternary compound, such as SnPbSSe, SnPbSeTe, SnPbSTe, and/or the like; or one or more combinations thereof.

Examples of the Group IV element or compound may include: a single element compound, such as Si, Ge, and/or the like; a binary compound, such as SiC, SiGe, and/or the like; or one or more combinations thereof.

Each element included in a multi-element compound, such as the binary compound, the ternary compound, and the quaternary compound, may be present at a substantially uniform concentration or non-uniform concentration in a particle.

In an embodiment, the third semiconductor compound may include a binary compound, a ternary compound, a quaternary compound, or one or more combinations thereof.

In an embodiment, A³ may include a Group II element, a Group III element, or a combination thereof.

For example, A³ may include beryllium (Be), magnesium (Mg), calcium (Ca), strontium (Sr), barium (Ba), zinc (Zn), cadmium (Cd), mercury (Hg), scandium (Sc), aluminum (Al), gallium (Ga), indium (In), thallium (Tl), or one or more combinations thereof.

In an embodiment, B³ may include a Group V element, a Group VI element, or a combination thereof.

For example, B³ may include vanadium (V), niobium (Nb), nitrogen (N), phosphorus (P), arsenic (As), antimony (Sb), oxygen (O), sulfur (S), selenium (Se), tellurium (Te), or one or more combinations thereof.

In an embodiment, the third semiconductor compound may include a Group II-VI semiconductor compound, a Group III-V semiconductor compound, a Group II-III-V semiconductor compound, a Group III-VI semiconductor compound, or one or more combinations thereof.

For example, the third semiconductor compound may be: CdS, CdSe, CdTe, ZnS, ZnSe, ZnTe, ZnO, HgS, HgSe, HgTe, MgSe, MgS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, CdZnSeS, CdZnSeTe, CdZnSTe, CdHgSeS, CdHgSeTe, CdHgSTe, HgZnSeS, HgZnSeTe, or HgZnSTe;
GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, or InAlPSb;
InZnP, InGaZnP, or InAlZnP;
GaS, GaSe, Ga₂Se₃, GaTe, InS, InSe, In₂S₃, In₂Se₃, InTe, InGaS₃, or InGaSe₃; or one or more combinations thereof.

In an embodiment, A³ may be identical to or different from A¹ and/or A².

In an embodiment, B³ may be identical to or different from B¹ and/or B².

In an embodiment, an average particle diameter D50 of the quantum dot 200 may be greater than or equal to about 1 nm and less than or equal to about 10 nm.

In an embodiment, the second shell 30 may have a single-layer structure or a multi-layer structure.

In an embodiment, the quantum dot 200 may have a substantially spherical shape.

In an embodiment, a photoluminescence efficiency of the quantum dot 200 may be greater than or equal to about 50% and less than or equal to about 95%, greater than or equal to about 50% and less than or equal to about 90%, or greater than or equal to about 50% and less than or equal to about 80%.

In an embodiment, a maximum emission wavelength in a PL spectrum of the quantum dot 200 may be in a range of about 450 nm to about 600 nm, about 450 nm to about 580 nm, or about 530 nm to about 580 nm.

In an embodiment, a full width at half maximum (FWHM) of the quantum dot 200 may be less than or equal to about 70 nm or less than or equal to about 65 nm.

In an embodiment, the quantum dot 200 may be prepared by a method of preparing a quantum dot to be described in more detail.

### Preparation Method of Quantum Dot

A method of preparing the quantum dot may include:
injecting a first solvent into a first reaction vessel;
preparing a first composition by injecting a first semiconductor compound into the first reaction vessel; and
forming a first shell by injecting a second composition including a second precursor into the first reaction vessel.

In an embodiment, the first semiconductor compound may include A¹ and B¹,
the second precursor may include A² and B²
A¹ and A² may each independently be a metal element and may be different from each other, and
B¹ and B² may each independently be a non-metal element.

In an embodiment, the second precursor may form a complex including A² and B².

The term “complex including A² and B²” as utilized herein refers to a state in which a metal element A², and a non-metal element B², or a combination thereof are paired with each other. However, the complex is not limited to a state in which A² and B² are bonded to each other to form a particle, and refers to a state in which A² and B² are mixed with each other.

For example, the complex may further include a ligand so that A², B², a ligand, or one or more combinations thereof may be paired with each other.

The complex may further include water or fatty acid.

In an embodiment, A¹ and A² may each independently include a Group II element, a Group III element, or a combination thereof.

In an embodiment, B¹ and B² may each independently include a Group V element, a Group VI element, or a combination thereof.

In an embodiment, A¹ and A² may each independently include beryllium (Be), magnesium (Mg), calcium (Ca), strontium (Sr), barium (Ba), zinc (Zn), cadmium (Cd), mercury (Hg), scandium (Sc), aluminum (Al), gallium (Ga), indium (In), thallium (Tl), or one or more combinations thereof.

In an embodiment, B¹ and B² may each independently include vanadium (V), niobium (Nb), nitrogen (N), phosphorus (P), arsenic (As), antimony (Sb), oxygen (O), sulfur (S), selenium (Se), tellurium (Te), or one or more combinations thereof.

In an embodiment, B¹ and B² may be identical to or different from each other.

In an embodiment, the first semiconductor compound may be represented by Formula 1:

A¹¹₁₋ₓ₁A¹²ₓ₁B¹³_{y1} Formula 1

wherein, in Formula 1,
A¹¹ may be a Group III element,
A¹² may be a Group II element,
B¹¹ may be a Group V element or a Group VI element,
x1 may be an integer greater than or equal to 0 or less than or equal to 1, and
y1 may be an integer greater than 0 and less than or equal to 1.

In one or more embodiments, the first semiconductor compound may be represented by Formula 1-1:

In₁₋ₓ₁Znₓ₁P_{y1} Formula 1-1

wherein, in Formula 1-1,
x1 may be an integer greater than or equal to 0 and less than or equal to 1, and
y1 may be an integer greater than 0 and less than or equal to 1.

In an embodiment, by the forming of the first shell, the first shell covering the first semiconductor compound may be formed.

In an embodiment, the first shell may include a second semiconductor compound including A² and B². For example, the first shell may include (e.g., consist of) the second semiconductor compound.

In an embodiment, the second semiconductor compound may be represented by Formula 2:

A²¹₁₋ₓ₂A²²ₓ₂B²¹_{y2} Formula 2

wherein, in Formula 2,
A²¹ may be a Group III element,
A²² may be a Group II element,
B²² may be a Group V element or a Group VI element,
x2 may be an integer greater than or equal to 0 or less than or equal to 1, and
y2 may be an integer greater than 0 and less than or equal to 1.

In an embodiment, the first solvent may include an amine-based solvent.

The term “amine-based solvent” refers to a solvent including an amine group-containing compound.

In an embodiment, the first solvent may include a compound represented by Formula 3 or a combination thereof:

N(R₃₁)(R₃₂)(R₃₃) Formula 3

wherein, in Formula 3,
R₃₁ to R₃₃ may each independently be a C₁-C₆₀ alkyl group unsubstituted or substituted with at least one R₁₀ₐ, a C₂-C₆₀ alkenyl group unsubstituted or substituted with at least one R₁₀ₐ, or a C₂-C₆₀ alkynyl group unsubstituted or substituted with at least one R₁₀ₐ,
R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or one or more combinations thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or one or more combinations thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or one or more combinations thereof.

In an embodiment, the first solvent may include trioctylamine, triheptylamine, trihexylamine, tripentylamine, tributylamine, tripropylamine, trimethylamine, trimethylamine, or one or more combinations thereof.

In an embodiment, the second composition may further include a second solvent.

In an embodiment, the second solvent may be an amine-based solvent, and the amine-based solvent is the same as defined herein.

In an embodiment, following the injecting of the first solvent into the first reaction vessel,

the method may further include performing vacuum treatment on the first reaction vessel.

In an embodiment, following the performing of the vacuum treatment on the first reaction vessel,

the method may further include removing air and moisture in the first reaction vessel.

In an embodiment, the removing of the air and moisture in the first reaction vessel may include injecting a reducing agent into the first reaction vessel.

In an embodiment, the reducing agent may include fluoride, such as triethylamine trihydrofluoride.

In an embodiment, following the injecting of the first solvent into the first reaction vessel, the method may include raising a temperature of the first reaction vessel to a temperature in a range of about 150° C. to about 250° C.

In an embodiment, the preparing of the first composition may be performed at a temperature in a range of about 150° C. to about 250° C., for example, about 180° C. to about 230° C., or about 190° C. to about 210° C.

In an embodiment, following the preparing of the first composition,
the method may include raising a temperature of the first composition to a temperature in a range of about 250° C. to about 400° C.

In an embodiment, before the forming of the first shell,
the method may include forming a second precursor by mixing a third precursor including A² and a fourth precursor including B² in a second reaction vessel.

The second reaction vessel corresponds to a reaction vessel different from the first reaction vessel.

In an embodiment, a molar ratio of A² to B² may be satisfied within a range of about 99:1 to about 1:99, for example, about 80:20 to about 20:80, about 75:25 to about 25:75, or about 75:25 to about 50:50.

In an embodiment, the third precursor may include an inorganic salt.

In an embodiment, the third precursor may include A² and nitrogen (N).

For example, the third precursor may include nitrate of A², nitride of A², or a combination thereof.

In an embodiment, the third precursor may further include water or fatty acid.

In an embodiment, the water or the fatty acid may serve as a ligand of the third precursor.

In an embodiment, the fatty acid may include caprylic acid, capric acid, lauric acid, palmitoleic acid, oleic acid, stearic acid, or one or more combinations thereof.

For example, the third precursor may include gallium nitrate-hydrate (Ga(NO₃)₃·xH₂O), gallium nitrate-oleate (Ga(NA)₃₋ₓ(OA)ₓ), or a combination thereof.

In an embodiment, the fourth precursor may include trimethylsilyl phosphine ((TMS)₃P), tris(dimethylamino)phosphine, or a combination thereof.

In an embodiment, the forming of the first shell may be performed at a temperature in a range of about 250° C. to about 400° C., for example, about 270° C. to about 380° C., or about 280° C. to about 350° C.

In an embodiment, in the forming of the first shell, the second composition may be continuously injected into the first reaction vessel.

The expression “continuous injection” as utilized herein refers to injection of a composition with a substantially constant or non-constant injection rate according to the passage of time, rather than injection of a composition at once.

In an embodiment, in the forming of the first shell, the second composition may be substantially continuously injected into the first reaction vessel at a rate in a range of about 0.01 mL/min to about 0.05 mL/min.

In an embodiment, in the forming of the first shell, the second composition may be substantially continuously injected at a constant rate into the first reaction vessel.

In an embodiment, when the second composition is substantially continuously injected at a constant rate, in the first shell of the quantum dot, a concentration of A, a concentration of B², or/and a concentration of the second semiconductor compound may be substantially uniform.

In an embodiment, by adjusting the injection rate of the second composition, the concentration of A², the concentration of B², and/or the concentration of the second semiconductor compound in the first shell of the quantum dot may each have a concentration gradient that gradually (e.g., suitably) increases or decreases along a direction from the surface of the first shell (or interface between the first shell and the second shell) to the surface of the core 10.

In an embodiment, in the forming of the first shell, the injection time of the second composition into the first reaction vessel may be about 20 minutes to about 150 minutes.

In an embodiment, an average particle diameter of the quantum dot may increase in proportion to the injection time of the second composition into the first reaction vessel.

In an embodiment, in the forming of the first shell, the second composition may be injected into the first reaction vessel through a syringe pump, but is not limited thereto.

In an embodiment, following the forming of the first shell,
the method may include cooling the first reaction vessel to a temperature greater than or equal to 200° C. and less than or equal to 320° C.

In an embodiment, following the forming of the first shell,
the method may further include forming a second shell around (e.g., covering) at least a portion of the first shell.

That is, the quantum dot prepared by the preparation method may further include the second shell covering at least a portion of the first shell.

In an embodiment, the forming of the second shell may include injecting a fifth precursor including a metal element A³, and a sixth precursor including a non-metal element B³, into the first reaction vessel.

The second shell of the quantum dot prepared by the preparation method may include A³ and B³.

In an embodiment, A³ may include a Group II element, a Group III element, or a combination thereof, and
B³ may include a Group V element, a Group VI element, or a combination thereof.

In an embodiment, A³ may include beryllium (Be), magnesium (Mg), calcium (Ca), strontium (Sr), barium (Ba), zinc (Zn), cadmium (Cd), mercury (Hg), scandium (Sc), aluminum (Al), gallium (Ga), indium (In), thallium (Tl), or one or more combinations thereof. For example, A³ may be Zn.

In an embodiment, the fifth precursor may include dimethyl zinc, diethyl zinc, zinc acetate, zinc acetylacetonate, zinc oleate, zinc stearate, zinc iodide, zinc bromide, zinc chloride, zinc fluoride, zinc carbonate, zinc cyanide, zinc nitrate, zinc oxide, zinc peroxide, zinc perchlorate, zinc sulfate, or one or more combinations thereof.

In an embodiment, B³ may include vanadium (V), niobium (Nb), nitrogen (N), phosphorus (P), arsenic (As), antimony (Sb), oxygen (O), sulfur (S), selenium (Se), tellurium (Te), or one or more combinations thereof. For example, B³ may be S.

In an embodiment, A³ may be Zn.

In an embodiment, the sixth precursor may include tributylphosphine-sulfide (TBP-S), trioctylphosphine-sulfide (TOP-S), or a combination thereof.

Other details on the preparation method of the quantum dot will be understood by a person skilled in the art with reference to examples to be described in more detail.

When a quantum dot is prepared by a method of preparing a quantum dot of the present disclosure, the second precursor in which the metal element A² and the non-metal element B² coexist is injected into the first composition including the first semiconductor compound, and accordingly a shell of the quantum dot is substantially immediately formed on the first semiconductor compound. In this regard, occurrence of defects in the surface and crystals of the quantum dot caused by uneven exchange of cations and/or the like may be prevented or reduced.

Thus, by preventing or reducing the occurrence of the defects, non-luminous recombination may be prevented or reduced, resulting in prevention or reduction of leakage of electrons or holes within an optical member or an electronic apparatus, thereby improving efficiency and lifespan of the optical member or the electronic apparatus.

In some embodiments, the size and composition of the quantum dot may be substantially uniformly generated so that the quantum dot may have a narrow full width at half maximum (FWHM) and color purity thereof may be significantly improved. By including the quantum dot, high-quality optical member and electronic apparatus may be provided.

### Optical Member

The quantum dot may be utilized in one or more suitable optical members. Accordingly, another aspect of one or more embodiments of the present disclosure is directed toward providing an optical member including the quantum dot.

In an embodiment, the optical member may be a light control (e.g., a light controller or a light control circuit).

In one or more embodiments, the optical member may be a color filter, a color conversion member (converter or cirucit), a capping layer, a light-extraction efficiency enhancement layer, a selective light-absorption layer, or a polarizing layer.

### Apparatus

The quantum dot may be utilized in one or more suitable electronic apparatuses. Accordingly, another aspect of one or more embodiments of the present disclosure is directed toward providing an electronic apparatus including the quantum dot.

In an embodiment, an electronic apparatus may include: a light source; and a color conversion member arranged in an optical path of light emitted from the light source, wherein the color conversion member includes the quantum dot.

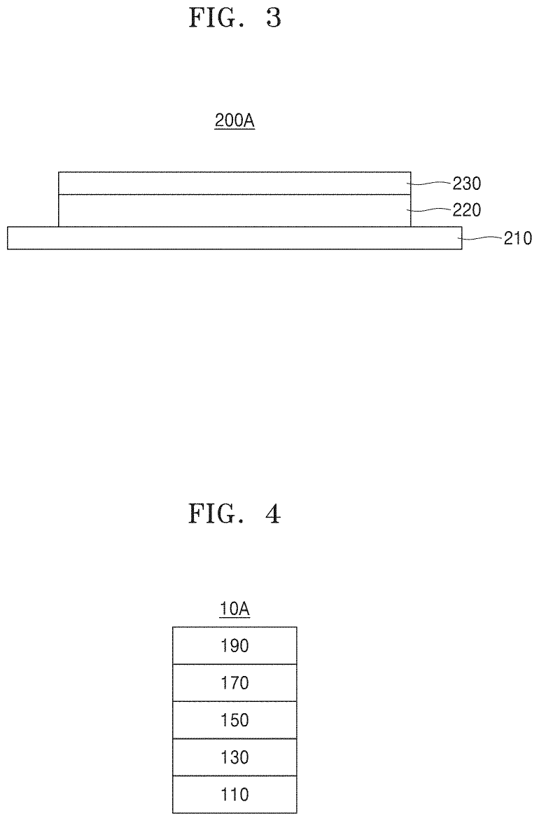

FIG. 3 is a schematic view showing a structure of an electronic apparatus 200A according to an embodiment. The electronic apparatus 200A of FIG. 3 includes: a substrate 210; a light source on the substrate 210; and a color conversion member 230 on the light source 220.

For example, the light source 220 may be a backlight unit (BLU) for utilize in a liquid crystal display (LCD), a fluorescent lamp, a light-emitting device, an organic light-emitting device, or a quantum-dot light-emitting device (QLED), or one or more combinations thereof. The color conversion member 230 may be arranged in at least one direction of travel of light emitted from the light source 220.

At least a region of the color conversion member 230 of the electronic apparatus 200A includes the quantum dot, and the region absorbs light emitted from the light source to emit blue light having a maximum light-emitting wavelength in a range of about 510 nm to about 540 nm.

Here, an embodiment in which the color conversion member 230 is arranged in at least one direction of travel of the light emitted from the light source 220 does not exclude other elements from being further included between the color conversion member 230 and the light source 220.

In an embodiment, between the light source 220 and the color conversion member 230, a polarizing plate, a liquid crystal layer, a light guide plate, a diffusion plate, a prism sheet, a microlens sheet, a luminance enhancing sheet, a reflective film, a color filter, or one or more combinations thereof may be additionally arranged.

In one or more embodiments, on the color conversion member 230, a polarizing plate, a liquid crystal layer, a light guide plate, a diffusion plate, a prism sheet, a microlens sheet, a luminance enhancing sheet, a reflective film, a color filter, or one or more combinations thereof may be additionally arranged.

The electronic apparatus 200A of FIG. 3, which is an embodiment according to the present disclosure, may have any of generally utilized/generally available (suitable) shapes, and accordingly, may further include generally utilized/generally available (suitable) structures.

In one or more embodiments, the electronic apparatus may have a structure including a light source, a light guide plate, a color conversion member, a first polarizing plate, a liquid crystal layer, a color filter, and a second polarizing plate that are sequentially arranged (in the stated order).

In one or more embodiments, the electronic apparatus may have a structure including a light source, a light guide plate, a first polarizing plate, a liquid crystal layer, a second polarizing plate, and a color conversion member that are sequentially arranged (in the stated order).

In the embodiments described above, the color filter may include a pigment and/or a dye. In the embodiments described above, one of the first polarizing plate and the second polarizing plate may be a vertical polarizing plate, and the other one may be a horizontal polarizing plate.

The quantum dot as described herein may be utilized as an emitter. Accordingly, in one or more embodiments, an electronic apparatus including a light-emitting device that includes: a first electrode; a second electrode facing the first electrode; and an emission layer between the first electrode and the second electrode may be provided, wherein the light-emitting device (for example, the emission layer of the light-emitting device) includes the quantum dot. The light-emitting device may further include a hole transport region between the first electrode and the emission layer, an electron transport region between the emission layer and the second electrode, or a combination thereof.

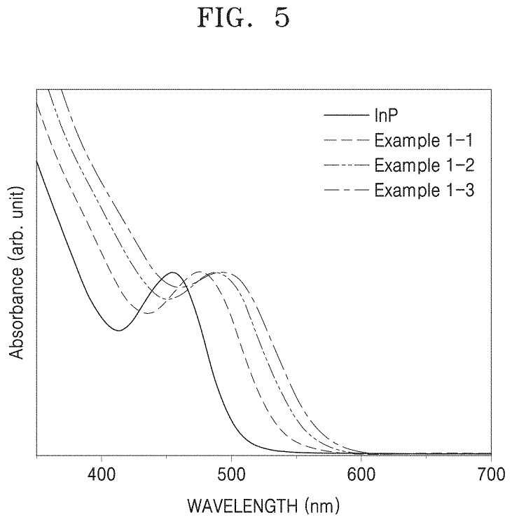

FIG. 4 is a schematic cross-sectional view showing a structure of a light-emitting device 10A according to an embodiment.

The light-emitting device 10A includes: a first electrode 110; a second electrode 190 facing the first electrode 110; an emission layer 150 that is between the first electrode 110 and the second electrode 190 and includes the quantum dot; a hole transport region between the first electrode 110 and the emission layer 150; and an electron transport region 170 between the emission layer 150 and the second electrode 190. Hereinafter, the layers of the light-emitting device 10A will be described in more detail.

### First Electrode 110

A substrate may be additionally arranged under the first electrode 110 or on the second electrode 150 of FIG. 4. For use as the substrate, a glass substrate or a plastic substrate, each having excellent or suitable mechanical strength, thermal stability, transparency, surface smoothness, ease of handling, and/or water resistance, may be utilized.

For example, in the embodiment of a top emission type or kind in which light from the light-emitting device 10A is emitted in a direction opposite to the substrate, the substrate need not to be transparent, and may be opaque or translucent. In this embodiment, the substrate may be formed of metal. When the substrate is formed of metal, the substrate may include carbon, iron, chromium, manganese, nickel, titanium, molybdenum, stainless steel (SUS), an Invar alloy, an Inconel alloy, a Kovar alloy, or one or more combinations thereof.

In some embodiments, a buffer layer, a thin-film transistor, and an organic insulating layer may be further provided between the substrate and the first electrode 110.

The first electrode 110 may be formed by, for example, depositing or sputtering a material for forming the first electrode 110 on the substrate. The first electrode 110 may be a reflective electrode, a semi-transmissive electrode, or a transmissive electrode. In an embodiment, to form the first electrode 110 as a transmissive electrode, a material for forming the first electrode 110 may include indium tin oxide (ITO), indium zinc oxide (IZO), tin oxide (SnO₂), zinc oxide (ZnO), gallium zinc oxide (GZO), aluminum zinc oxide (AZO), InZnSnOₓ (IZSO), ZnSnOₓ (ZSO), graphene, PEDOT:PSS, carbon nanotube, silver (Ag) nanowire, gold (Au) nanowire, metal mesh, or one or more combinations thereof. In one or more embodiments, to form the first electrode 110 as a semi-transmissive electrode or a reflective electrode, a material for the first electrode 110 may include magnesium (Mg), silver (Ag), aluminum (Al), aluminum-lithium (Al—Li), calcium (Ca), magnesium-indium (Mg—In), magnesium-silver (Mg—Ag), or one or more combinations thereof.

The first electrode 110 may have a single-layer structure or a multi-layer structure including multiple layers. For example, the first electrode 110 may have a three-layered structure of ITO/Ag/ITO.

### Hole Transport Region 130

The hole transport region 130 may have i) a single-layer structure including (e.g., consisting of) a single layer including a single material, ii) a single-layer structure including (e.g., consisting of) a single layer including multiple materials that are different from each other, or iii) a multi-layer structure including (e.g., consisting of) multiple layers including multiple materials that are different from each other.

The hole transport region 130 may include a hole injection layer, a hole transport layer, an emission auxiliary layer, an electron blocking layer, or one or more combinations thereof.

For example, the hole transport region 130 may have a single-layer structure including a single layer including multiple materials that are different from each other, or a multi-layer structure of a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, wherein the constituent layers of each structure are stacked sequentially from the first electrode 110 (in the stated order).

The hole transport region 130 may include an amorphous inorganic or inorganic material. The inorganic material may include NiO, MoO₃, Cr₂O₃, or Bi₂O₃. Further, the inorganic material may include: a p-type or kind inorganic semiconductor in which an iodide, bromide, or chloride of Cu, Ag, or Au is doped with a non-metal such as O, S, Se, or Te; a p-type or kind inorganic semiconductor in which a compound including Zn is doped with a metal such as Cu, Ag, or Au and with a non-metal such as N, P, As, Sb, or Bi; or a voluntary p-type or kind inorganic semiconductor such as ZnTe.

The organic material may include m-MTDATA, TDATA, 2-TNATA, NPB (NPD), β-NPB, TPD, Spiro-TPD, Spiro-NPB, methylated-NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate (PANI/PSS), polyvinylcarbazole (PVK), a compound represented by Formula 201, a compound represented by Formula 202, or one or more combinations thereof:

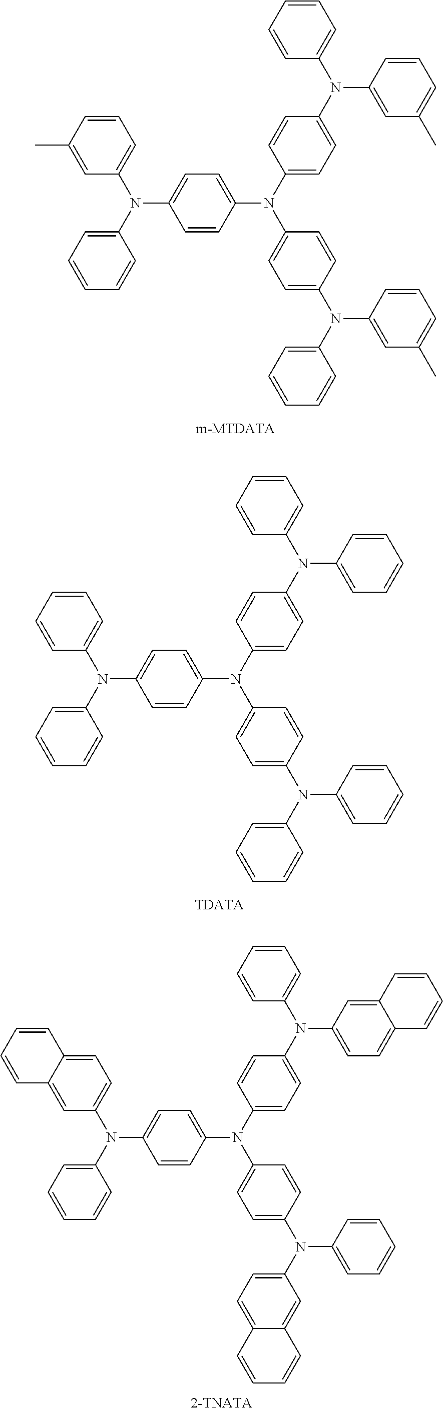

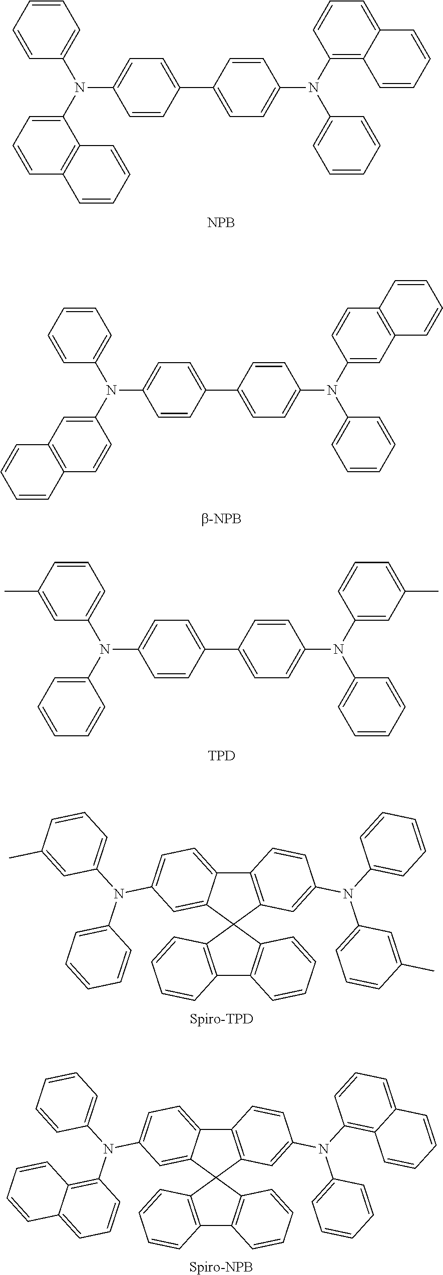

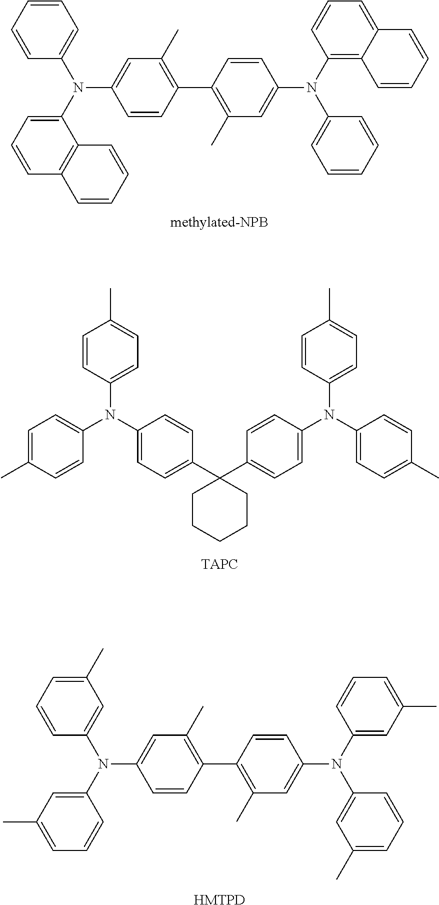

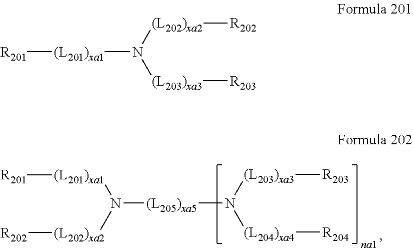

wherein, in Formulae 201 and 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be linked to each other, via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic unsubstituted or substituted with at least one R₁₀ₐ(for example, a carbazole group),
R₂₀₃ and R₂₀₄ may optionally be bonded to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and
na1 may be an integer from 1 to 4.

A thickness of the hole transport region 130 may be in a range of about 50 Å to about 10,000 Å. For example, the thickness of the hole transport region 130 may be in a range of about 100 Å to about 4,000 Å. When the hole transport area 130 includes a hole injection layer, a hole transport layer, or a combination thereof, a thickness of the hole injection layer may be in a range of about 100 Å to about 9,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region 130, the hole injection layer, and the hole transport layer are within these ranges, satisfactory (suitable) hole transporting characteristics may be obtained without a substantial increase in driving voltage.

The emission auxiliary layer may increase light-emission efficiency by compensating for an optical resonance distance according to the wavelength of light emitted by the emission layer, and the electron blocking layer may block or reduce the leakage of electrons from the emission layer to the hole transport region 130. Materials that may be included in the hole transport region 130 may be included in the emission auxiliary layer and the electron blocking layer.

p-Dopant

The hole transport region 130 may further include, in addition to the materials described above, a charge-generation material for the improvement of conductive characteristics. The charge-generation material may be substantially uniformly or non-uniformly dispersed in the hole transport region 130 (for example, in the form of a single layer including (e.g., consisting of) a charge generation material).

The charge-generation material may be, for example, a p-dopant.

For example, the p-dopant may have a lowest unoccupied molecular orbital (LUMO) energy level of less than or equal to −3.5 eV.

In an embodiment, the p-dopant may include a quinone derivative, a cyano group-containing compound, a compound including element EL1 and element EL2, or one or more combinations thereof.

Examples of the quinone derivative may include TCNQ, F4-TCNQ, and/or the like.

Examples of the cyano group-containing compound may include HAT-CN, a compound represented by Formula 221, and/or the like:

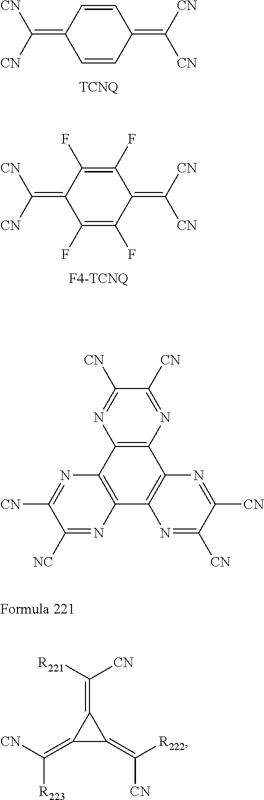

wherein, in Formula 221,
R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
at least one of R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or one or more combinations thereof; or one or more combinations thereof.

In the compound including element EL1 and element EL2, element EL1 may be metal, metalloid, or a combination thereof, and element EL2 may be non-metal, metalloid, or a combination thereof.

Examples of the metal may include an alkali metal (for example, lithium (Li), sodium (Na), potassium (K), rubidium (Rb), cesium (Cs), etc.); alkaline earth metal (for example, beryllium (Be), magnesium (Mg), calcium (Ca), strontium (Sr), barium (Ba), etc.); transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), etc.); post-transition metal (for example, zinc (Zn), indium (In), tin (Sn), etc.); and/or lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), etc.).

Examples of the metalloid may include silicon (Si), antimony (Sb), tellurium (Te), and/or the like.

Examples of the non-metal may include oxygen (O), halogen (for example, F, Cl, Br, I, etc.), and/or the like.

Examples of the compound including element EL1 and element EL2 may include metal oxide, metal halide (for example, metal fluoride, metal chloride, metal bromide, metal iodide, etc.), metalloid halide (for example, metalloid fluoride, metalloid chloride, metalloid bromide, metalloid iodide, etc.), metal telluride, or one or more combinations thereof.

Examples of the metal oxide may include tungsten oxide (for example, WO, W₂O₃, WO₂, WO₃, W₂O₅, etc.), vanadium oxide (for example, VO, V₂O₃, VO₂, V₂O₅, etc.), molybdenum oxide (MoO, Mo₂O₃, MoO₂, MoO₃, Mo₂O₅, etc.), rhenium oxide (for example, ReO₃, etc.), and/or the like.

Examples of the metal halide may include alkali metal halide, alkaline earth metal halide, transition metal halide, post-transition metal halide, lanthanide metal halide, and/or the like.

Examples of the alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, CsI, and/or the like.

Examples of the alkaline earth metal halide may include BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, BeI₂, MgI₂, CaI₂, SrI₂, BaI₂, and/or the like.

Examples of the transition metal halide may include titanium halide (for example, TiF₄, TiCl₄, TiBr₄, Til₄, etc.), zirconium halide (for example, ZrF₄, ZrCl₄, ZrBr₄, ZrI₄, etc.), hafnium halide (for example, HfF₄, HfCl₄, HfBr₄, HfI₄, etc.), vanadium halide (for example, VF₃, VCl₃, VBr₃, VI₃, etc.), niobium halide (for example, NbF₃, NbCl₃, NbBr₃, NbI₃, etc.), tantalum halide (for example, TaF₃, TaCl₃, TaBr₃, TaI₃, etc.), chromium halide (for example, CrF₃, CrCl₃, CrBr₃, CrI₃, etc.), molybdenum halide (for example, MoF₃, MoCl₃, MoBr₃, MoI₃, etc.), tungsten halide (for example, WF₃, WCl₃, WBr₃, WI₃, etc.), manganese halide (for example, MnF₂, MnCl₂, MnBr₂, MnI₂, etc.), technetium halide (for example, TcF₂, TcCl₂, TcBr₂, TcI₂, etc.), rhenium halide (for example, ReF₂, ReCl₂, ReBr₂, ReI₂, etc.), iron halide (for example, FeF₂, FeCl₂, FeBr₂, FeI₂, etc.), ruthenium halide (for example, RuF₂, RuCl₂, RuBr₂, RuI₂, etc.), osmium halide (for example, OsF₂, OsCI₂, OsBr₂, OsI₂, etc.), cobalt halide (for example, CoF₂, COCl₂, CoBr2, CoI₂, etc.), rhodium halide (for example, RhF₂, RhCl₂, RhBr₂, RhI₂, etc.), iridium halide (for example, IrF₂, IrCl₂, IrBr₂, IrI₂, etc.), nickel halide (for example, NiF₂, NiCl₂, NiBr₂, NiI₂, etc.), palladium halide (for example, PdF₂, PdCl₂, PdBr₂, PdI₂, etc.), platinum halide (for example, PtF₂, PtCl₂, PtBr₂, PtI₂, etc.), copper halide (for example, CuF, CuCl, CuBr, CuI, etc.), silver halide (for example, AgF, AgCl, AgBr, AgI, etc.), gold halide (for example, AuF, AuCl, AuBr, AuI, etc.), and/or the like.

Examples of the post-transition metal halide may include zinc halide (for example, ZnF₂, ZnCl₂, ZnBr₂, ZnI₂, etc.), indium halide (for example, InI₃, etc.), tin halide (for example, SnI₂, etc.), and/or the like.

Examples of the lanthanide metal halide may include YbF, YbF₂, YbF₃, SmF₃, YbCl, YbCl₂, YbCl₃ SmCl₃, YbBr, YbBr₂, YbBr₃ SmBr₃, YbI, YbI₂, YbI₃, SmI₃, and/or the like.

Examples of the metalloid halide may include antimony halide (for example, SbCl₅, etc.) and/or the like.

Examples of the metal telluride may include alkali metal telluride (for example, Li₂Te, a na₂Te, K₂Te, Rb₂Te, Cs₂Te, etc.), alkaline earth metal telluride (for example, BeTe, MgTe, CaTe, SrTe, BaTe, etc.), transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, etc.), post-transition metal telluride (for example, ZnTe, etc.), lanthanide metal telluride (for example, LaTe, CeTe, PrTe, NdTe, PmTe, EuTe, GdTe, TbTe, DyTe, HoTe, ErTe, TmTe, YbTe, LuTe, etc.), and/or the like.

### Emission Layer 150

The emission layer 150 may be a quantum-dot single layer or have a structure in which two or more quantum-dot layers are stacked. For example, the emission layer 150 may be a quantum-dot single layer or have a structure in which 2 to 100 quantum-dot layers are stacked.

The emission layer 150 may include the quantum dot as described in the present disclosure.

The emission layer 150 may further include, in addition to the quantum dot as described herein, a dispersion medium in which the quantum dots are dispersed in a naturally coordinated form. The dispersion medium may include an organic solvent, a polymer resin, or a combination thereof. The dispersion medium may be any suitable transparent medium as long as it does not affect (adversely affect) the optical performance of the quantum dot, is not deteriorated by light, does not reflect light, or does not absorb light. For example, the organic solvent may include toluene, chloroform, ethanol, octane, or one or more combinations thereof, and the polymer resin may include epoxy resin, silicone resin, polystyrene resin, acrylate resin, or one or more combinations thereof.

The emission layer 150 may be formed by coating the hole transport region 130 with a quantum dot-containing composition for forming the emission layer, and volatilizing a portion or more of the solvent from the composition for forming the emission layer.

For example, as the solvent, water, hexane, chloroform, toluene, octane, and/or the like may be utilized.

The coating of the composition for forming the emission layer may be performed by utilizing a spin coat method, a casting method, a micro gravure coating method, a gravure coating method, a bar coating method, a roll coating method, a wire bar coating method, a dip coating method, a spray coating method, a screen printing method, a flexographic method, an offset printing method, an ink jet printing method, and/or the like.

When the light-emitting device 10A is a full-color light-emitting device, the emission layer 150 may include emission layers that emit light of different colors according to individual subpixels.

For example, the emission layer 150 may be patterned into a first color emission layer, a second color emission layer, and a third color emission layer according to individual subpixels. Here, at least one emission layer of these emission layers may include the quantum dot. For example, the first-color emission layer may be a quantum dot-emission layer including the quantum dot, and the second-color emission layer and the third-color emission layer may each be an organic emission layer including an organic compound. Here, the first color through the third color may be different colors from each other, and for example, the first color through the third color may have different maximum emission wavelengths. The first color through the third color may be white when combined with each other.

In one or more embodiments, the emission layer 150 may further include a fourth color emission layer. At least one emission layer of the first color emission layer to the fourth color emission layer may be a quantum dot-emission layer including the quantum dot, and the others thereof may each be an organic emission layer including an organic compound. As such, other one or more suitable modifications may be available. Here, the first color through the fourth color may be different colors from each other, and for example, the first color through the fourth color may have different maximum emission wavelengths. The first color through the fourth color may be white when combined with each other.

In an embodiment, the light-emitting device 10A may have a structure in which two or more emission layers emitting light of the same or different colors are stacked to contact each other or to be spaced apart from (separated from) each other. At least one of the two or more emission layers may be a quantum dot-emission layer including the quantum dot, and the others thereof may each be an organic emission layer including an organic compound. As such, other one or more suitable modifications may be available. For example, the light-emitting device 10A may include a first color emission layer and a second color emission layer, and the first color and the second color may be the same color or different colors. And for example, both (e.g., simultaneously) the first color and the second color may be blue.

The emission layer 150 may further include, in addition to the quantum dot, at least one selected from among an organic compound and a semiconductor compound.

The organic compound may include a host and a dopant. A host and a dopant that are generally utilized/generally available in organic light-emitting devices may be utilized as the host and dopant.

The semiconductor compound may be organic and/or inorganic perovskite.

### Electron Transport Region 170

The electron transport region 170 may have: i) a single-layer structure including (e.g., consisting of) a single layer including (e.g., consisting of) a single material; ii) a single-layer structure including (e.g., consisting of) a single layer including (e.g., consisting of) multiple materials that are different from each other; or iii) a multi-layer structure including multiple layers including materials that are different from each other.

The electron transport region 170 may include at least one layer selected from among a buffer layer, a hole blocking layer, an electron control layer, an electron transport layer, and an electron injection layer. However, embodiments of the present disclosure are not limited thereto.

For example, the electron transport region 170 may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein the constituent layers of each structure are stacked sequentially from the emission layer. However, embodiments of the present disclosure are not limited thereto.

The electron transport region 170 may include a conductive metal oxide. Examples of the conductive metal oxide may include ZnO, TiO₂, WO₃, SnO₂, In₂O₃, Nb₂O₅, Fe₂O₃, CeO₂, SrTiO₃, Zn₂SnO₄, BaSnO₃, In₂S₃, ZnSiO, PC60BM, PC70BM, Mg-doped ZnO (ZnMgO), Al-doped ZnO (AZO), Ga-doped ZnO (GZO), In-doped ZnO (IZO), Al-doped TiO₂, Ga-doped TiO₂, In-doped TiO₂, Al-doped WO₃, Ga-doped WO₃, In-doped WO₃, Al-doped SnO₂, Ga-doped SnO₂, In-doped SnO₂, Mg-doped In₂O₃, Al-doped In₂O₃, Ga-doped In₂O₃, Mg-doped Nb₂O₅, Al-doped Nb₂O₅, Ga-doped Nb₂O₅, Mg-doped Fe₂O₃, Al-doped Fe₂O₃, Ga-doped Fe₂O₃, In-doped Fe₂O₃, Mg-doped CeO₂, Al-doped CeO₂, Ga-doped CeO₂, In-doped CeO₂, Mg-doped SrTiO₃, Al-doped SrTiO₃, Ga-doped SrTiO₃, In-doped SrTiO₃, Mg-doped Zn₂SnO₄, Al-doped Zn₂SnO₄, Ga-doped Zn₂SnO₄, In-doped Zn₂SnO₄, Mg-doped BaSnO₃, Al-doped BaSnO₃, Ga-doped BaSnO₃, In-doped BaSnO₃, Mg-doped In₂S₃, Al-doped In₂S₃, Ga-doped In₂S₃, In-doped In₂S₃, Mg-doped ZnSiO, Al-doped ZnSiO, Ga-doped ZnSiO, In-doped ZnSiO, or one or more combinations thereof.

The organic material may include a generally utilized/generally available compound having electron transport properties, such as 2,9-dimethyl-4,7-diphenyl-1,10-phenanthroline (BCP), 4,7-diphenyl-1,10-phenanthroline (Bphen), Alq₃, BAlq, 3-(biphenyl-4-yl)-5-(4-tert-butylphenyl)-4-phenyl-4H-1,2,4-triazole (TAZ), NTAZ, and/or the like:

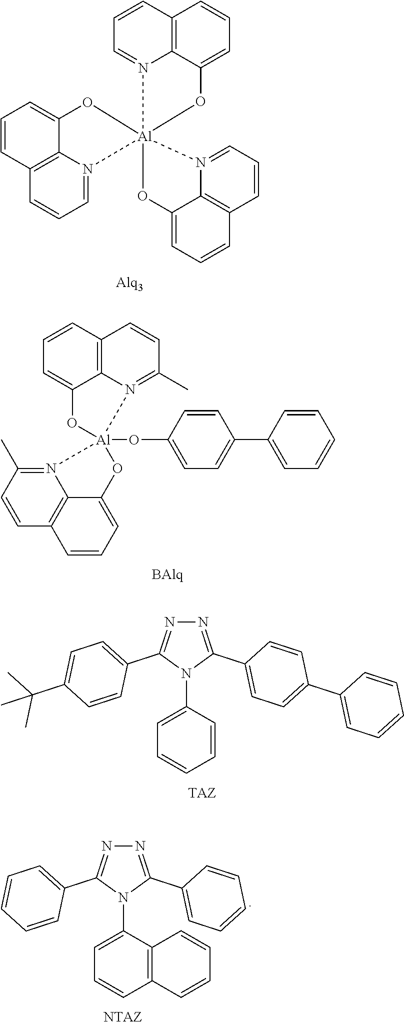

In some embodiments, the organic material may be a metal-free compound including at least one π electron-deficient nitrogen-containing C₁-C₆₀ cyclic group.

For example, the electron transport region 170 may include a compound represented by Formula 601:

[Ar₆₀₁]ₓₑ₁₁-[(L₆₀₁)ₓₑ₁-R₆₀₁]ₓₑ₂₁ Formula 601

wherein, in Formula 601,
Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each be the same as described in connection with Q₁,
xe21 may be 1, 2, 3, 4, or 5, and
at least one of Ar₆₀₁, L₆₀₁, and R₆₀₁ may each independently be a π electron-deficient nitrogen-containing C₁-C₆₀ cyclic group unsubstituted or substituted with at least one R₁₀ₐ.

The electron transport region 170 may have a thickness of about 160 Å to about 5000 Å, for example, about 100 Å to about 4000 Å. When the electron transport region 170 includes a buffer layer, a hole blocking layer, an electron control layer, an electron transport layer, or one or more combinations thereof, a thickness of the buffer layer, the hole blocking layer, or the electron control layer may be in a range of about 20 Å to about 1,000 Å, for example, about 30 Å to about 300 Å, and a thickness of the electron transport layer may be in a range of about 100 Å to about 1000 Å, for example, about 150 Å to about 500 Å. When the thickness of the buffer layer, the hole blocking layer, the electron control layer, the electron transport layer, and/or the electron transport layer is within these ranges, satisfactory (suitable) electron transporting characteristics may be obtained without a substantial increase in driving voltage.

The electron transport region 170 (for example, the electron transport layer in the electron transport region) may further include, in addition to the materials described above, a metal-containing material.

The metal-containing material may include an alkali metal complex, an alkaline earth metal complex, or a combination thereof. The metal ion of an alkali metal complex may be a Li ion, a Na ion, a K ion, a Rb ion, or a Cs ion, and the metal ion of an alkaline earth metal complex may be a Be ion, a Mg ion, a Ca ion, a Sr ion, or a Ba ion. A ligand coordinated with the metal ion of the alkali metal complex or the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or one or more combinations thereof.

For example, the metal-containing material may include a Li complex. The Li complex may include, for example, Compound ET-D1 (LiQ) or ET-D2:

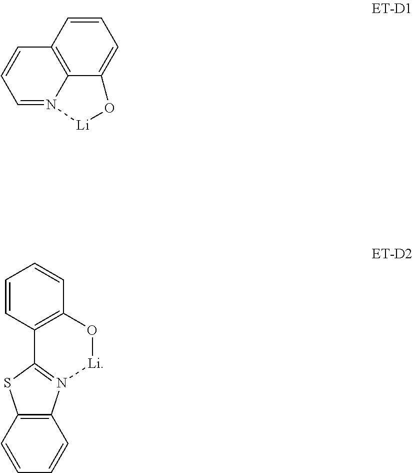

The electron transport region 170 may include an electron injection layer that facilitates the injection of electrons from the second electrode 190. The electron injection layer may directly contact the second electrode 190.

The electron injection layer may have: i) a single-layered structure including (e.g., consisting of) a single layer including (e.g., consisting of) a single material, ii) a single-layered structure including (e.g., consisting of) a single layer including (e.g., consisting of) a plurality of different materials, or iii) a multi-layered structure including a plurality of layers including different materials.

The electron injection layer may include an alkali metal, alkaline earth metal, a rare earth metal, an alkali metal-containing compound, alkaline earth metal-containing compound, a rare earth metal-containing compound, an alkali metal complex, an alkaline earth metal complex, a rare earth metal complex, or one or more combinations thereof.

The alkali metal may include Li, Na, K, Rb, Cs, or one or more combinations thereof. The alkaline earth metal may include Mg, Ca, Sr, Ba, or one or more combinations thereof. The rare earth metal may include Sc, Y, Ce, Tb, Yb, Gd, or one or more combinations thereof.

The alkali metal-containing compound, the alkaline earth metal-containing compound, and/or the rare earth metal-containing compound may be oxides, halides (for example, fluorides, chlorides, bromides, iodides, etc.), or tellurides of the alkali metal, the alkaline earth metal, and/or the rare earth metal, or one or more combinations thereof.

The alkali metal-containing compound may include: an alkali metal oxide, such as Li₂O, Cs₂O, K₂O, and/or the like; alkali metal halides, such as LiF, NaF, CsF, KF, LiI, NaI, CsI, Kl, and/or the like; or one or more combinations thereof. The alkaline earth metal-containing compound may include an alkaline earth metal compound, such as BaO, SrO, CaO, BaₓSr₁₋ₓO (wherein x is a real number satisfying 0<x<1), BaₓCa₁₋ₓO (wherein x is a real number satisfying 0<x<1), and/or the like. The rare earth metal-containing compound may include YbF₃, ScF₃, Sc₂O₃, Y₂O₃, Ce₂O₃, GdF₃, TbF₃, YbI₃, ScI₃, TbI₃, or one or more combinations thereof. In an embodiment, the rare earth metal-containing compound may include lanthanide metal telluride. Examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, Lu₂Te₃, and/or the like.

The alkali metal complex, the alkaline earth-metal complex, and the rare earth metal complex may include i) one of ions of the alkali metal, the alkaline earth metal, and the rare earth metal and ii), as a ligand bonded to the metal ion, for example, hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenyl benzimidazole, hydroxyphenylbenzothiazole, bipyridine, phenanthroline, cyclopentadiene, or one or more combinations thereof.

In an embodiment, the electron injection layer may include (e.g., consist of) an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or one or more combinations thereof, as described above. In one or more embodiments, the electron injection layer may further include an organic material (for example, a compound represented by Formula 601).

In an embodiment, the electron injection layer may include (e.g., consist of) i) an alkali metal-containing compound (for example, alkali metal halide), ii) a) an alkali metal-containing compound (for example, alkali metal halide); and b) an alkali metal, an alkaline earth metal, a rare earth metal, or one or more combinations thereof. For example, the electron injection layer may be a Kl:Yb co-deposited layer, an RbI:Yb co-deposited layer, a Li:F co-deposited layer, and/or the like.

When the electron injection layer further includes an organic material, the alkali metal, the alkaline earth metal, the rare earth metal, the alkali metal-containing compound, the alkaline earth metal-containing compound, the rare earth metal-containing compound, the alkali metal complex, the alkaline earth-metal complex, the rare earth metal complex, or one or more combinations thereof may be substantially uniformly or non-uniformly dispersed in a matrix including the organic material.

A thickness of the electron injection layer may be in a range of about 1 Å to about 100 Å, and, for example, about 3 Å to about 90 Å. When the thickness of the electron injection layer is within these ranges, satisfactory (suitable) electron injection characteristics may be obtained without a substantial increase in driving voltage.

### Second Electrode 190

A second electrode 190 is on the electron transport region 170. The second electrode 190 may be a cathode, which is an electron injection electrode. As a material for forming the second electrode 190, a metal, an alloy, an electrically conductive compound, or one or more combinations thereof, having a low work function, may be utilized.

The second electrode 190 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or one or more combinations thereof. The second electrode 190 may be a transmissive electrode, a semi-transmissive electrode, or a reflective electrode.

The second electrode 190 may have a single-layer structure or a multi-layer structure including multiple layers.

The electronic apparatus (for example, a light-emitting apparatus) may further include, in addition to the light-emitting device 10A, i) a color filter, ii) a color conversion layer, or iii) both (e.g., simultaneously) a color filter and a color conversion layer. The color filter and/or the color conversion layer may be arranged in at least one direction of travel of light emitted from the light-emitting device 10A. For example, light emitted from the light-emitting device 10A may be blue light or white light. Details of the light-emitting device 10A may each independently be the same as described herein. In an embodiment, the color conversion layer may include a quantum dot. The quantum dot may be, for example, the quantum dot as described herein.

The electronic apparatus may further include a thin-film transistor, in addition to the light-emitting device 10A. The thin-film transistor may include a source electrode, a drain electrode, and an activation layer, and either the source electrode or the drain electrode may be electrically connected to either the first electrode 110 or the second electrode 190 of the light-emitting device 10A.

The thin-film transistor may further include a gate electrode, a gate insulating film, and/or the like.

The activation layer may include crystalline silicon, amorphous silicon, an organic semiconductor, an oxide semiconductor, and/or the like.

The electronic apparatus may further include a sealing portion that seals the light-emitting device 10A. The sealing portion may be between the light-emitting device 10A and the color filter and/or color conversion layer. The sealing portion allows light from the light-emitting device 10A to be extracted to the outside, and concurrently (e.g., simultaneously) prevents (reduces) ambient air and moisture from penetrating into the light-emitting device 10. The sealing portion may be a sealing substrate including a transparent glass substrate or a plastic substrate. The sealing portion may be a thin-film encapsulation layer including at least one layer of an organic layer and/or an inorganic layer. When the sealing portion is a thin-film encapsulation layer, the electronic apparatus may be flexible.

Various suitable functional layers may be additionally arranged on the sealing portion, in addition to the color filter and/or the color conversion layer, according to how the electronic apparatus is utilized. Examples of the functional layers may include a touch screen layer, a polarizing layer, and/or the like. The touch screen layer may be a pressure-sensitive touch screen layer, a capacitive touch screen layer, or an infrared touch screen layer. The authentication apparatus may be, for example, a biometric authentication apparatus that authenticates an individual by utilizing biometric information of a living body (for example, fingertips, pupils, etc.).

The authentication apparatus may further include, in addition to the organic light-emitting device 10A, a biometric information collector.

The electronic apparatus may be applied to one or more suitable displays, light sources, lighting, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, or endoscope displays), fish finders, one or more suitable measuring instruments, meters (for example, meters for a vehicle, an aircraft, and/or a vessel), projectors, and/or the like.

### Definition of Terms

The term “C₃-C₆₀ carbocyclic group” as utilized herein refers to a cyclic group consisting of carbon only as a ring-forming atom and having three to sixty carbon atoms, and the term “C₁-C₆₀ heterocyclic group” as utilized herein refers to a cyclic group that has one to sixty carbon atoms and further has, in addition to carbon, a heteroatom as a ring-forming atom. The C₃-C₆₀ carbocyclic group and the C₁-C₆₀ heterocyclic group may each be a monocyclic group consisting of one ring or a polycyclic group in which two or more rings are condensed with each other. For example, the number of ring-forming atoms of the C₁-C₆₀ heterocyclic group may be from 3 to 61.

The “cyclic group” as utilized herein may include both (e.g., simultaneously) the C₃-C₆₀ carbocyclic group and the C₁-C₆₀ heterocyclic group.

The term “π electron-rich C₃-C₆₀ cyclic group” as utilized herein refers to a cyclic group that has three to sixty carbon atoms and does not include *—N═*′ as a ring-forming moiety, and the term “π electron-deficient nitrogen-containing C₁-C₆₀ cyclic group” as utilized herein refers to a heterocyclic group that has one to sixty carbon atoms and includes *—N═*′ as a ring-forming moiety.

For example,
the C₃-C₆₀ carbocyclic group may be i) a T1 group or ii) a condensed cyclic group in which two or more T1 groups are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
the C₁-C₆₀ heterocyclic group may be i) a T2 group, ii) a condensed cyclic group in which at least two T2 groups are condensed with each other, or iii) a condensed cyclic group in which at least one T2 group and at least one T1 group are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like.),
the π electron-rich C₃-C₆₀ cyclic group may be i) a T1 group, ii) a condensed cyclic group in which at least two T1 groups are condensed with each other, iii) a T3 group, iv) a condensed cyclic group in which at least two T3 groups are condensed with each other, or v) a condensed cyclic group in which at least one T3 group and at least one T1 group are condensed with each other (for example, the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, and/or the like),
the π electron-deficient nitrogen-containing C₁-C₆₀ cyclic group may be i) a T4 group, ii) a condensed cyclic group in which at least two T4 groups are condensed with each other, iii) a condensed cyclic group in which at least one T4 group and at least one T1 group are condensed with each other, iv) a condensed cyclic group in which at least one T4 group and at least one T3 group are condensed with each other, or v) a condensed cyclic group in which at least one T4 group, at least one T1 group, and at least one T3 group are condensed with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like),
the T1 group may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group,
the T2 group may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
the T3 group may be a furan group, a thiophene group, a 1H-pyrrole group, a silole group, or a borole group, and
the T4 group may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “the cyclic group, the C₃-C₆₀ carbocyclic group, the C₁-C₆₀ heterocyclic group, the π electron-rich C₃-C₆₀ cyclic group, or the π electron-deficient nitrogen-containing C₁-C₆₀ cyclic group” as utilized herein refer to a group condensed to any cyclic group, a monovalent group, or a polyvalent group (for example, a divalent group, a trivalent group, a tetravalent group, etc.) according to the structure of a formula for which the corresponding term is utilized. For example, the “benzene group” may be a benzo group, a phenyl group, a phenylene group, and/or the like, which may be easily understood by one of ordinary skill in the art according to the structure of a formula including the “benzene group.”

Examples of the monovalent C₃-C₆₀ carbocyclic group and the monovalent C₁-C₆₀ heterocyclic group are a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₀ heteroaryl group, a monovalent non-aromatic condensed polycyclic group, and/or a monovalent non-aromatic condensed heteropolycyclic group. Examples of the divalent C₃-C₆₀ carbocyclic group and the monovalent C₁-C₆₀ heterocyclic group are a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₀ heteroarylene group, a divalent non-aromatic condensed polycyclic group, and/or a substituted or unsubstituted divalent non-aromatic condensed heteropolycyclic group.

The term “C₁-C₆₀ alkyl group” as utilized herein refers to a linear or branched aliphatic hydrocarbon monovalent group that has one to sixty carbon atoms, and specific examples thereof are a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and/or a tert-decyl group. The term “C₁-C₆₀ alkylene group” as utilized herein refers to a divalent group having the same structure as the C₁-C₆₀ alkyl group.

The term “C₂-C₆₀ alkenyl group” as utilized herein refers to a monovalent hydrocarbon group having at least one carbon-carbon double bond in the middle or at the terminus of the C₂-C₆₀ alkyl group, and examples thereof are an ethenyl group, a propenyl group, a butenyl group, and/or the like. The term “C₂-C₆₀ alkenylene group” as utilized herein refers to a divalent group having the same structure as the C₂-C₆₀ alkenyl group.

The term “C₂-C₆₀ alkynyl group” as utilized herein refers to a monovalent hydrocarbon group having at least one carbon-carbon triple bond in the middle or at the terminus of the C₂-C₆₀ alkyl group, and examples thereof are an ethynyl group, a propynyl group, and/or the like. The term “C₂-C₆₀ alkynylene group” as utilized herein refers to a divalent group having the same structure as the C₂-C₆₀ alkynyl group.

The term “C₁-C₆₀ alkoxy group” as utilized herein refers to a monovalent group represented by —OA₁₀₁ (wherein A₁₀₁ is the C₁-C₆₀ alkyl group), and examples thereof are a methoxy group, an ethoxy group, an isopropyloxy group, and/or the like.

The term “C₃-C₁₀ cycloalkyl group” as utilized herein refers to a monovalent saturated hydrocarbon cyclic group having 3 to 10 carbon atoms, and examples thereof are a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, a bicyclo[2.2.2]octyl group, and/or the like. The term “C₃-C₁₀ cycloalkylene group” as utilized herein refers to a divalent group having the same structure as the C₃-C₁₀ cycloalkyl group.

The term “C₁-C₁₀ heterocycloalkyl group” as utilized herein refers to a monovalent cyclic group of 1 to 10 carbon atoms, further including, in addition to carbon atoms, at least one heteroatom, as ring-forming atoms, and examples thereof are a 1,2,3,4-oxatriazolidinyl group, a tetrahydrofuranyl group, a tetrahydrothiophenyl group, and/or the like. The term “C₁-C₁₀ heterocycloalkylene group” as utilized herein refers to a divalent group having the same structure as the C₁-C₁₀ heterocycloalkyl group.

The term “C₃-C₁₀ cycloalkenyl group” as utilized herein refers to a monovalent cyclic group that has three to ten carbon atoms and at least one carbon-carbon double bond in the ring thereof and no aromaticity, and examples thereof are a cyclopentenyl group, a cyclohexenyl group, a cycloheptenyl group, and/or the like. The term “C₃-C₁₀ cycloalkenylene group” as utilized herein refers to a divalent group having the same structure as the C₃-C₁₀ cycloalkenyl group.

The term “C₁-C₁₀ heterocycloalkenyl group” as utilized herein refers to a monovalent cyclic group of 1 to 10 carbon atoms, further including, in addition to carbon atoms, at least one heteroatom, as ring-forming atoms, and having at least one carbon-carbon double bond in the cyclic structure thereof. Examples of the C₁-C₁₀ heterocycloalkenyl group are a 4,5-dihydro-1,2,3,4-oxatriazolyl group, a 2,3-dihydrofuranyl group, a 2,3-dihydrothiophenyl group, and/or the like. The term “C₁-C₁₀ heterocycloalkenylene group” as utilized herein refers to a divalent group having the same structure as the C₁-C₁₀ heterocycloalkenyl group.

The term “C₆-C₆₀ aryl group” as utilized herein refers to a monovalent group having a carbocyclic aromatic system of 6 to 60 carbon atoms, and the term “C₆-C₆₀ arylene group” as utilized herein refers to a divalent group having a carbocyclic aromatic system of 6 to 60 carbon atoms. Examples of the C₆-C₆₀ aryl group are a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, and/or the like. When the C₆-C₆₀ aryl group and the C₆-C₆₀ arylene group each include two or more rings, the rings may be condensed with each other.

The term “C₁-C₆₀ heteroaryl group” as utilized herein refers to a monovalent group having a heterocyclic aromatic system of 1 to 60 carbon atoms, further including, in addition to carbon atoms, at least one heteroatom, as ring-forming atoms. The term “C₁-C₆₀ heteroarylene group” as utilized herein refers to a divalent group having a heterocyclic aromatic system of 1 to 60 carbon atoms, further including, in addition to carbon atoms, at least one heteroatom, as ring-forming atoms. Examples of the C₁-C₆₀ heteroaryl group are a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and/or a naphthyridinyl group. When the C₁-C₆₀ heteroaryl group and the C₁-C₆₀ heteroarylene group each include two or more rings, the rings may be condensed with each other.

The term “monovalent non-aromatic condensed polycyclic group” as utilized herein refers to a monovalent group (for example, having 8 to 60 carbon atoms) having two or more rings condensed to each other, only carbon atoms as ring-forming atoms, and no aromaticity in its entire molecular structure. Examples of the monovalent non-aromatic condensed polycyclic group are an indenyl group, a fluorenyl group, a spiro-bifluorenyl group, a benzofluorenyl group, an indenophenanthrenyl group, an indeno anthracenyl group, and/or the like. The term “divalent non-aromatic condensed polycyclic group” as utilized herein refers to a divalent group having the same structure as the monovalent non-aromatic condensed polycyclic group described above.

The term “monovalent non-aromatic condensed heteropolycyclic group” as utilized herein refers to a monovalent group (for example, having 1 to 60 carbon atoms) having two or more rings condensed to each other, further including, in addition to carbon atoms, at least one heteroatom, as ring-forming atoms, and having non-aromaticity in its entire molecular structure. Examples of the monovalent non-aromatic condensed heteropolycyclic group are a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indeno carbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and/or a benzothienodibenzothiophenyl group. The term “divalent non-aromatic condensed heteropolycyclic group” as utilized herein refers to a divalent group having the same structure as the monovalent non-aromatic condensed heteropolycyclic group described above.

The term “C₆-C₆₀ aryloxy group” as utilized herein indicates —OA₁₀₂ (wherein A₁₀₂ is the C₆-C₆₀ aryl group), and the term “C₆-C₆₀ arylthio group” as utilized herein indicates —SA₁₀₃ (wherein A₁₀₃ is the C₆-C₆₀ aryl group).

The term “C₇-C₆₀ arylalkyl group” as utilized herein refers to -A₁₀₄A₁₀₅ (wherein A₁₀₄ is a C₁-C₅₄ alkylene group, and A₁₀₅ is a C₆-C₅₉ aryl group), and the term “C₂-C₆₀ heteroarylalkyl group” as utilized herein refers to -A₁₀₆A₁₀₇ (wherein A₁₀₆ is a C₁-C₅₉ alkylene group, and A₁₀₇ is a C₁-C₅₉ heteroaryl group).

The term “R₁₀ₐ” as utilized herein may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or one or more combinations thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or one or more combinations thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

In the present disclosure, Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or one or more combinations thereof; a C₇-C₆₀ arylalkyl group; or a C₂-C₆₀ heteroarylalkyl group.

The term “heteroatom” as utilized herein refers to any atom other than a carbon atom. Examples of the heteroatom are O, S, N, P, Si, B, Ge, Se, or one or more combinations thereof.

The term “third-row transition metal” as utilized herein includes Hf, Ta, W, Re, Os, Ir, Pt, Au, and/or the like.

“Ph” as utilized herein refers to a phenyl group, “Me” as utilized herein refers to a methyl group, “Et” as utilized herein refers to an ethyl group, “ter-Bu” or “Bu^{t}” as utilized herein refers to a tert-butyl group, and “OMe” as utilized herein refers to a methoxy group.

The term “biphenyl group” as utilized herein refers to “a phenyl group substituted with a phenyl group.” In other words, the “biphenyl group” is a substituted phenyl group having a C₆-C₆₀ aryl group as a substituent.

The term “terphenyl group” as utilized herein refers to “a phenyl group substituted with a biphenyl group.” In other words, the “terphenyl group” is a substituted phenyl group having, as a substituent, a C₆-C₆₀ aryl group substituted with a C₆-C₆₀ aryl group.

* and *′ as utilized herein, unless defined otherwise, each refer to a binding site to a neighboring atom in a corresponding formula or moiety.

Hereinafter, embodiments of the quantum dot preparation method and the quantum dot prepared according to the same will be described in more detail with reference to the following synthesis examples and examples.

### EXAMPLES

### Example 1-1

### 1. Preparation of First Semiconductor Compound (InP Quantum Dot)

1-octadecene (10 mL) as a reaction solvent, indium(III) acetate (0.6 mmol) as an indium precursor, zinc acetate (1.2 mmol) as a zinc precursor, and oleic acid (2.4 mmol) and lauric acid (1.8 mmol) as carboxyl compounds were heated in a vacuum state to form an indium-zinc-ligand complex. Then, trimethylsilylphosphine (0.4 mmol) was added to trioctylphosphine (1 mL) in a glove box under the state where substantially all the air and moisture have been removed. The mixture was filled in a syringe and rapidly injected into a flask at 170° C. Then, the reaction was allowed for 30 minutes at 240° C. Next, the reaction mixture was rapidly cooled and purified by centrifugation three times or more after adding ethanol thereto, thereby preparing InP quantum dots as a first semiconductor compound.

### 2. Preparation of Second Composition

### Preparation of Third Precursor (Gallium Nitrate-Oleate)

Methanol (640 mL) as a reaction solvent, oleic acid (20 mL) as a carboxyl compound, and sodium hydroxide (2.56 g) as a base material were rapidly stirred at room temperature to form sodium oleate. Then, methanol (40 mL) as a reaction solvent and gallium (III) nitrate hydrate (4 g) as a gallium precursor were stirred and rapidly injected into a reactor. Then, the reaction was allowed for 1 hour. The precipitated white precipitate was separated, and through a washing process utilizing methanol several times, gallium nitrate-oleate as a third precursor was prepared.

Preparation of Second Composition (Gallium-Phosphorus-Ligand Complex)

trioctylamine (8 mL) as a reaction solvent and gallium nitrate-oleate (2 mmol) as a gallium precursor which is a third precursor were heated in a vacuum state to remove air and moisture from the reaction vessel. Next, trimethylsilylphosphine (1 mmol) as a fourth precursor was added to trioctylphosphine (3 mL) in a glove box under the state where the reaction solution was cooled at room temperature. The mixture was filled in a syringe, rapidly injected into a flask, and stirred, thereby preparing a second composition including a gallium-phosphorus-ligand complex.

### 3. Formation of First Shell (InP/GaP Quantum Dots)

Trioctylamine (10 mL) as a reaction solvent and triethylamine-trihydrofluoride (0.1 mL) as a fluorinating agent were heated in a vacuum state to remove air and moisture from the reaction vessel. After removing the air and moisture from the reaction vessel, the temperature of the reaction solution was raised to 200° C., the prepared InP quantum dot was injected into the reaction vessel, and the reaction was allowed for 10 minutes.

Next, the reaction mixture was heated at 330° C., and the second composition filled in a syringe was injected continuously thereinto at a rate of 0.016 mL/min for 30 minutes through a syringe pump. Then, the resulting mixture was cooled to 280° C. and purified by centrifugation three times or more after adding ethanol thereto, thereby preparing InP/GaP quantum dots of Example 1-1.

### Examples 1-2 and 1-3

InP/GaP quantum dots were prepared in substantially the same manner as in Example 1-1, except that the second composition was injected according to the injection time of the second composition shown in Table 1 instead of 30 minutes in the section “3. Formation of first shell” of Example 1-1.

### Evaluation Example 1

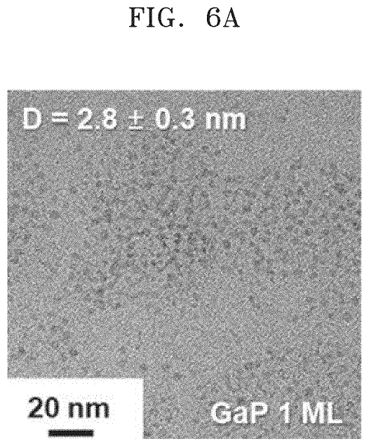

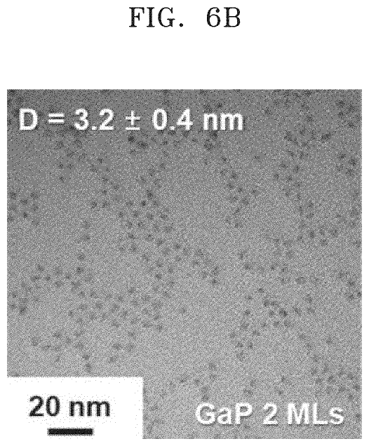

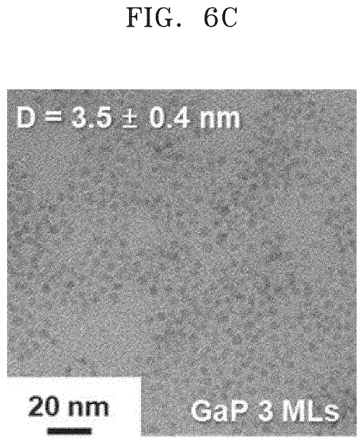

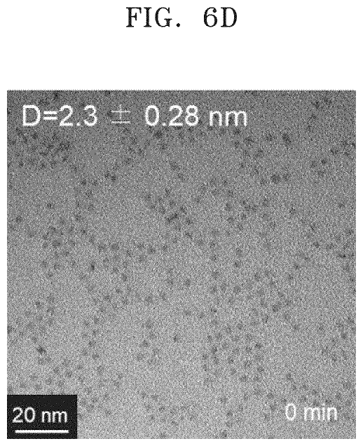

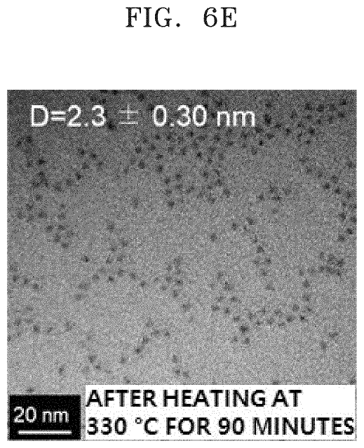

Absorbance spectra (by Shimadzu UV3600) of the quantum dots of Examples 1-1 to 1-3 are shown in FIG. 5, and TEM images (by Philips Tecnai F30 (300 kV)) of the same quantum dots are shown in FIG. 6.

(FIG. 6A: Example 1-1, FIG. 6B: Example 1-2, FIG. 6C: Example 1-3, FIG. 6D: Control group (InP quantum dots))

In some embodiments, wavelengths at 1s-peak in the absorbance spectrum of FIG. 5 and average particle diameters of the quantum dots measured in FIG. 6 are shown in Table 1. Here, the average particle diameter of the core was 2.3 nm, and measured by a TEM.

TABLE 1

| | | Wavelength | Average | Average |
|---|---|---|---|---|
| | Injection | (nm) at | particle | particle |
| | time of | 1s-peak in | diameter of | diameter of |
| | second | absorbance | quantum dots | core |
| | composition | spectrum | (D50, nm) | (D50, nm) |
| Control | — | 463 | 2.3 | — |
| group (InP | | | | |
| quantum | | | | |
| dots) | | | | |
| Example 1-1 | 30 minutes | 483 | 2.8 | 2.3 |
| Example 1-2 | 60 minutes | 496 | 3.2 | 2.3 |
| Example 1-3 | 90 minutes | 501 | 3.5 | 2.3 |

Referring to FIG. 5 and Table 1, it was confirmed that the wavelength at the 1s-peak in the absorbance spectrum of the quantum dots was gradually shifted to a longer wavelength as the injection time of the second composition increased. Also, referring to FIG. 6 and Table 1, it was confirmed that the average particle diameter of the quantum dots gradually increased as the injection time of the second composition increased. Therefore, it was confirmed that the size of the quantum dots increased as the injection time of the second composition increased.

### Evaluation Example 2

Regarding the control group (InP quantum dots), the TEM images before and after heating to 330° C. at 90 minutes are shown in FIGS. 6D and 6E.

When comparing FIGS. 6D and 6E, it was confirmed that the particle size remained constant. Thus, it was confirmed that the core size of the quantum dots (InP) remained constant without being affected by temperature, and that only the size of the quantum dots increased as the thickness of the first shell increased according to the injection time of the second composition, while the core size of the quantum dots remained constant.

### Example 2-1

### 1. Preparation of First Semiconductor Compound (InP Quantum Dots)

1-octadecene (10 mL) as a reaction solvent, indium(III) acetate (0.6 mmol) as an indium precursor, zinc acetate (1.2 mmol) as a zinc precursor, and oleic acid (2.4 mmol) and lauric acid (1.8 mmol) as carboxyl compounds were heated in a vacuum state to form an indium-zinc-ligand complex. Then, trimethylsilylphosphine (0.4 mmol) was added to trioctylphosphine (1 mL) in a glove box under the state where all the air and moisture have been removed. The mixture was filled in a syringe and rapidly injected into a flask at 170° C. Then, the reaction was allowed for 30 minutes at 240° C. Next, the reaction mixture was rapidly cooled and purified by centrifugation three times or more after adding ethanol thereto, thereby preparing InP quantum dots as a first semiconductor compound.

### 2. Preparation of Second Composition

### Preparation of Third Precursor (Gallium Nitrate-Oleate)

Methanol (640 mL) as a reaction solvent, oleic acid (20 mL) as a carboxyl compound, and sodium hydroxide (2.56 g) as a base material were rapidly stirred at room temperature to form sodium oleate. Then, methanol (40 mL) as a reaction solvent and gallium (III) nitrate hydrate (4 g) as a gallium precursor were stirred and rapidly injected into a reactor. Then, the reaction was allowed for 1 hour. The precipitated white precipitate was separated, and through a washing process utilizing methanol several times, gallium nitrate-oleate as a third precursor was prepared.

Preparation of Second Composition (Gallium-Phosphorus-Ligand Complex)

trioctylamine (8 mL) as a reaction solvent and gallium nitrate-oleate (2 mmol) as a gallium precursor which is a third precursor were heated in a vacuum state to remove air and moisture from the reaction vessel. Next, trimethylsilylphosphine (1 mmol) as a fourth precursor was added to trioctylphosphine (3 mL) in a glove box under the state where the reaction solution was cooled at room temperature. The mixture was filled in a syringe, rapidly injected into a flask, and stirred, thereby preparing a second composition including a gallium-phosphorus-ligand complex.

### 3. Preparation of Fifth Precursor (Zinc Oleate)

Trioctylamine (10 mL) as a reaction solvent, zinc acetate (5 mmol) as a zinc precursor, and oleic acid (10 mmol) as a carboxyl compound were heated in a vacuum state to remove air and moisture from the reaction vessel. Then, after filling the reaction vessel with argon gas and heating for 10 minutes at 300° C. to remove residual acetic acid, the temperature was maintained at 90° C., thereby preparing zinc oleate.

### 4. Preparation of Sixth Precursor (Trioctylphosphine-Sulfide)

In a glove box, trioctylphosphine (5 mL) as a reaction solvent and sulfur powder (10 mmol) as a sulfur precursor were heated for 1 hour at 230° C., thereby preparing trioctylphosphine-sulfide (TOP-S) as a fourth precursor.

### 5. Formation of First and Second Shells (InP/GaP/ZnS Quantum Dots)

Trioctylamine (10 mL) as a reaction solvent and triethylamine-trihydrofluoride (0.1 mL) as a fluorinating agent were heated in a vacuum state to remove air and moisture from the reaction vessel. After removing the air and moisture from the reaction vessel, the temperature of the reaction solution was raised to 200° C., the prepared InP quantum dot was injected into the reaction vessel, and the reaction was allowed for 10 minutes.

Next, the reaction mixture was heated at 330° C., and the second composition filled in a syringe was injected continuously thereinto at a rate of 0.016 mL/min for 30 minutes through a syringe pump. Then, the resulting mixture was cooled to 280° C., the fifth precursor, i.e., zinc oleate solution (2.5 mL), was injected thereinto, and the sixth precursor, i.e., trioctylphosphine-S (TOPS, 0.32 mL), were injected thereinto to stack ZnS as a second shell. Then, the reaction was allowed for 10 minutes after heating the reaction mixture at 320° C.

Then, a cooling process was rapidly performed, and the resulting mixture was purified by centrifugation three times or more after adding ethanol thereto, thereby preparing InP/GaP/ZnS quantum dots of Example 2-1.

### Examples 2-2 and 2-3

InP/GaP quantum dots were prepared in substantially the same manner as in Example 1-1, except that the second composition was injected according to the injection time of the second composition shown in Table 1 instead of 30 minutes in the section “5. Formation of first and second shells” of Example 2-1.

### Evaluation Example 2

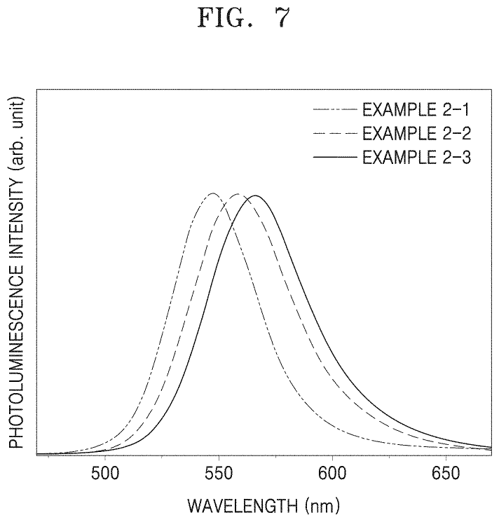

Photoluminescence (PL) spectra of the quantum dots of Examples 2-1 to 2-3 were measured utilizing by utilizing Otsuka QE-2100 according to an absorbance of 0.2 at 450 nm excitation, and the results are shown in FIG. 7.

Also, peak wavelength and full width at half maximum (FWHM) in the PL spectra were measured, and luminescence efficiency of the quantum dots of Examples 2-1 to 2-3 were measured utilizing Hamamatsu C11347. The results are shown in Table 2.

TABLE 2

| | Injection | Peak | Luminescence | |
|---|---|---|---|---|
| | time of | wavelength | efficiency (%) | |
| | second | (nm) in PL | (emitted photon)/ | FWHM |
| | composition | spectrum | (absorbed photon) | (nm) |
| Example 2-1 | 30 minutes | 546 nm | 71% | 45 nm |
| Example 2-2 | 60 minutes | 557 nm | 60% | 56 nm |
| Examples 2 | 90 minutes | 565 nm | 56% | 63 nm |
| and 3 | | | | |

Referring to FIG. 7 and Table 2, it was confirmed that the peak wavelength in the PL spectrum of the quantum dots was gradually shifted to a longer wavelength as the injection time of the second composition increased, meaning that the size of the quantum dots gradually increased.

Also, referring to Table 2, it was confirmed that the quantum dots of Examples 2-1 to 2-3 all showed the luminescence efficiency of greater than equal to 50% and the FWHM of less than 70 nm. In particular, it was confirmed that the quantum dots of Example 2-1 had excellent or suitable luminescence efficiency of greater than equal to 70% and the low FWHM of less than or equal to 50 nm.

According to the one or more embodiments, a quantum dot prepared by a method of preparing a quantum dot according to the present disclosure may have excellent or suitable luminescence characteristics and high stability by preventing or reducing occurrence of defects in the surface and crystals of the quantum dot and having substantially uniform size and composition of a core and a shell of the quantum dot, and thus utilize of the quantum dot may provide high-quality optical member and electronic apparatus. Although the present disclosure has been described with reference to the Synthesis Examples and Examples, these examples are provided for illustrative purpose only, and one of ordinary skill in the art may understand that these examples may have one or more suitable modifications and other examples equivalent thereto.

Accordingly, the scope of the present disclosure should be determined by the technical concept of the claims.

The use of “may” when describing embodiments of the present disclosure refers to “one or more embodiments of the present disclosure.”

As used herein, the singular forms “a”, “an” and “the” are intended to include the plural forms as well, unless the context clearly indicates otherwise.

As used herein, the term “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this disclosure is intended to include all higher numerical limitations subsumed therein. Accordingly, Applicant reserves the right to amend this disclosure, including the claims, to expressly recite any sub-range subsumed within the ranges expressly recited herein.

The electronic apparatus or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the present disclosure, when particles are spherical, “diameter” indicates an average particle diameter, and when the particles are non-spherical, the “diameter” indicates a major axis length. The diameter (or size) of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter (or size) is referred to as D50. D50 refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the drawings, it will be understood by those of ordinary skill in the art that one or more suitable changes in form and details may be made therein without departing from the spirit and scope as defined by the following claims and equivalents thereof.

What is claimed is:

1. A method of preparing a quantum dot, the method comprising:
injecting a first solvent into a first reaction vessel;
preparing a first composition by injecting a first semiconductor compound into the first reaction vessel; and
forming a first shell by injecting a second composition comprising a second precursor into the first reaction vessel,
wherein the first semiconductor compound comprises A¹ and B¹,
the second precursor comprises A² and B²,
A¹ and A² are each independently a metal element and are different from each other, and
B¹ and B² are each independently a non-metal element.

2. The method of claim 1, wherein the second precursor comprises a complex comprising A² and B².

3. The method of claim 1, wherein A¹ and A² are each independently a Group II element, a Group III element, or any combination thereof, and
B¹ and B² are each independently a Group V element, a Group VI element, or any combination thereof.

4. The method of claim 1, wherein A¹ and A² each independently comprise beryllium (Be), magnesium (Mg), calcium (Ca), strontium (Sr), barium (Ba), zinc (Zn), cadmium (Cd), mercury (Hg), scandium (Sc), aluminum (Al), gallium (Ga), indium (In), thallium (Tl), or any combination thereof, and
B¹ and B² each independently comprise vanadium (V), niobium (Nb), nitrogen (N), phosphorus (P), arsenic (As), antimony (Sb), oxygen (O), sulfur (S), selenium (Se), tellurium (Te), or any combination thereof.

5. The method of claim 1, wherein the first solvent comprises an amine-based solvent.

6. The method of claim 1, wherein the forming of the first shell is performed at a temperature in a range of about 250° C. to about 400° C.

7. The method of claim 1, wherein, in the forming of the first shell, the second composition is continuously injected into the first reaction vessel at a rate in a range of about 0.01 mL/min to about 0.05 mL/min.

8. The method of claim 1, wherein, in the forming of the first shell, the second composition is continuously injected into the first reaction vessel at a constant rate.

9. The method of claim 1, further comprising, before the forming of the first shell, forming the second precursor by mixing a third precursor comprising A² and a fourth precursor comprising B² in a second reaction vessel.

10. The method of claim 9, wherein the third precursor further comprises N.

11. The method of claim 1, further comprising, after the forming of the first shell, forming a second shell covering at least a portion of the first shell.

12. The method of claim 11, wherein the forming of the second shell comprises injecting a fifth precursor comprising a metal element A³, and a sixth precursor comprising a non-metal element B³, into the first reaction vessel.

13. A quantum dot prepared by the method of claim 1, the quantum dot comprising:
a core comprising the first semiconductor compound; and
the first shell covering the core,
wherein the first shell comprises A² and B².

14. The quantum dot of claim 13, further comprising a second shell covering at least a portion of the first shell.

15. The quantum dot of claim 13, wherein the quantum dot is spherical.

16. The quantum dot of claim 13, wherein a maximum emission wavelength of a PL spectrum of the quantum dot is in a range of about 450 nm to about 580 nm.

17. An optical member comprising the quantum dot of claim 13.

18. An electronic apparatus comprising the quantum dot of claim 13.

19. The electronic apparatus of claim 18, further comprising:
a light source, the light source being configured to emit a path of light; and
a color conversion member arranged in the path of light,
wherein the quantum dot is comprised in the color conversion member.

20. The electronic apparatus of claim 18, further comprising a light-emitting device comprising:
a first electrode;
a second electrode facing the first electrode; and
an emission layer between the first electrode and the second electrode,
wherein the quantum dot is comprised in the light-emitting device.
